(19) United States
(12) Patent Application Publication
(10) Pub. No.: US 2026/0127341 A1
(43) Pub. Date: May 7, 2026

(54) PHYSICS-INFORMED INTELLIGENT COMPUTATIONAL MODEL BASED ON SENSOR DATA

(71) Applicant: Transcend Engineering and Technology, LLC, Bethel, VT (US)

(72) Inventors: Stephen P. Farrington, Stockbridge, VT (US); Andrea R. Pearce, Starksboro, VT (US)

(21) Appl. No.: 19/427,859

(22) Filed: Dec. 19, 2025

Related U.S. Application Data
(63) Continuation of application No. PCT/US2024/034863, filed on Jun. 20, 2024.
(60) Provisional application No. 63/521,974, filed on Jun. 20, 2023.

(51) Int. Cl. G06F 30/27

(52) U.S. Cl. CPC G06F 30/27

(57) ABSTRACT

Physics-based intelligent machine learning based computational modeling of a complex natural phenomenon that uses sensor data as input is disclosed. The computational modeling includes computing sensor performance characteristics of a physical sensor used in measuring attributes of a physical system. The modeling also includes simulating, based on a process-based model, the physical system to produce simulated data corresponding to one or more physical state variables of the natural system, and applying, to the simulated data, the computed sensor performance characteristics of the physical sensor to corrupt the simulated data to generate one or more simulated sensor responses that more closely approximates an actual output of the physical sensor. A training dataset is generated from the simulated data, which reflects the simulated sensor responses, and input parameters for the process-based model to train a machine learning model.

### RELATED APPLICATIONS

This application is a continuation of International Application No. PCT/US2024/034863, filed June 20, 2024, titled “Physics-Informed Intelligent Computational Model Based On Sensor Data,” which claims priority to U.S. Provisional Application No. 63/521,974, filed June 20, 2023, titled “Intelligent Computational Model Based on Sensor Data,” each of which is incorporated herein by reference in its entirety.

### STATEMENT REGARDING FEDERALLY SPONSORED RESEARCH OR DEVELOPMENT

Aspects of this disclosure were made with U.S. Government support under a contract awarded by the US Army Corps of Engineers, contract # W913E519C0003. The government has certain rights in the disclosure.

### TECHNICAL FIELD

The present disclosure generally relates to an intelligent computational model, and more particularly, to developing a machine learning based computational model of a complex physical phenomenon that uses sensor data as input. In some implementations, the disclosure relates to developing a machine learning based computational model of attributes of fluid flow in unsaturated porous media that uses sensor data as input.

### BACKGROUND

In machine learning, training data may be used to train a machine learning model. Obtaining training data for machine learning may entail some human input. Depending on the machine learning techniques and the kind of model being trained the amount and quality of training data may vary.

By giving a machine learning model training data and modifying its parameters to reduce the error between the anticipated output and the actual output, a machine learning model is trained. This process may be performed numerous times until the model reaches an acceptable level of accuracy, driven by an optimization algorithm such as gradient descent or stochastic gradient descent using backpropagation.

### SUMMARY

According to an aspect of the present disclosure, a method describing an intelligent machine learning based computational modeling of a complex physical phenomenon is disclosed. The method uses sensor data as input. The method includes computing sensor performance characteristics of a physical sensor used in measuring attributes of a physical system. The method also includes simulating, based on a process-based model, the physical system to produce simulated data corresponding to one or more physical state variables of the natural system, and applying, to the simulated data, the computed sensor performance characteristics of the physical sensor to corrupt the simulated data to generate one or more simulated sensor responses that more closely approximates an actual output of the physical sensor. In some cases, the physical phenomenon may be a natural phenomenon. A training dataset is generated to train a machine learning model, the training dataset is generated using the simulated sensor responses, the simulated data, and/or inputs of the process-based model. In some implementations, the simulated sensor responses may replace, in the training dataset, simulated data from which the simulated sensor responses were produced. Put another way, a simulated sensor response is produced by applying at least a sensor performance characteristic to a state variable represented in the simulated data; that state variable may be replaced by the simulated sensor response in the training data or that state variable may be replaced in the simulated data before storing the simulated data in the training dataset. The training dataset may include a plurality of training examples. Thus, as used herein, the simulated data stored in the training dataset reflects any simulated sensor responses generated from the simulated data. Each training example may identify an attribute of the physical system as a training target. The training target may be a physical system property. The training target may be a state variable. In some implementations, a simulated sensor response may be identified as a training target. The training example may identify multiple state variables as target training targets. Each training example may include a time series of simulation data for the training target(s). Each training example may include an instance of a time series of simulation data. The process-based model may be a virtual replica of the physical system that uses realistic data and/or other input data to mimic behavior of the physical system. The physical sensor can be one or a plurality of sensors of the same type that work to measure a given state variable of the physical system or one of a plurality of different types that work to measure one or more state variables of the physical system.

In one implementation, the method includes performing the simulating step and the applying step a number of times, each of the number of times corresponding to a scenario. Each scenario may be defined by a number of input parameters representing attributes of the physical system being simulated. The attributes of a physical system can be invariant, meaning that the attribute does not change during the simulation. Such invariant attributes are referred to as physical system properties or just properties. An example of a physical system property is a domain definition. A domain definition specifies the arrangement of physical objects or materials in the physical system, including intrinsic and extrinsic physical properties. Examples of properties include properties of materials that exist in the physical system. For instance, the spatial variability of an intrinsic property of an immobile material within the domain of the simulation is an aspect of a domain definition. The sequence and thickness of each layer in a multi-layer profile of soil along with each layer's porosity, permeability, and other physical properties is an example of a domain definition.

Attributes of a physical system can also be temporally variant (e.g., time-dependent). Such temporally variant attributes are also referred to as physical state variables or just state variables. Where the physical state variables are used as input to a model, a simulation, or another process they can also be referred to as physical state parameters or state parameters. Examples of state variables include temperature, pressure, flux, chemical concentrations, or any other physical attribute measurable by a physical sensor. State variables are not limited to attributes measurable by sensors, however. For example, state variables can include the in situ permeability of a region of soil. Another example of a state variable is the rate of flux of groundwater in a specific direction. Yet another example of a state variable is the presence or absence of an underground tunnel within the simulation domain. Some state variables may be initial conditions for a physical system simulation. Initial conditions are state variables used as input parameters for a physical system as the start of a simulation. In other words, the input conditions specify the condition (state variable value) of time-varying attributes of the physical system at the start of the simulation. For example, initial conditions may include the starting temperature, pressure, or chemical concentration. State variables may also include variable boundary conditions. Boundary conditions represent how the system behaves at the boundaries of the domain explicitly represented in the simulation. A variable boundary condition may also be considered a state variable of the physical system. Boundary conditions may also be static. Static boundary conditions may be considered properties of the physical system. A number of scenarios may be generated with each scenario corresponding to a simulation that produces a collection of unmodified simulated data and a collection of simulated sensor responses obtained by corrupting, based on sensor response characteristics of at least some of the unmodified simulated data. The machine learning model is trained based on at least the simulated sensor responses as training inputs.

According to an implementation of the present disclosure a computer program product is disclosed. The computer program product includes one or more computer-readable storage devices and program instructions stored on at least one of the one or more tangible storage devices, the program instructions executable by a processor, the program instructions including program instructions to intelligently model a complex physical phenomenon. The computer program product includes program instructions to compute sensor performance characteristics of a physical sensor used in measuring attributes of a physical system. The computer program product also includes program instructions to simulate, based on a process-based model, the physical system to produce simulated data corresponding to one or more physical state variables of the natural system. The computer program product includes program instructions to apply, to the simulated data, the computed sensor performance characteristics of the physical sensor to corrupt the simulated data to generate one or more simulated sensor responses that more closely approximates an actual output of the physical sensor. The computer program product includes program instructions to generate a training dataset to train the machine learning model, the training dataset being generated using the simulated data. The simulated data stored in the training dataset may be modified so that the simulated data reflects the simulated sensor responses and not the state variables used to produce the simulated sensor responses. In other words, a simulated sensor response is produced by applying at least a sensor performance characteristic to a state variable represented in the simulated data; that state variable may be replaced by the simulated sensor response in the training data or that state variable may be replaced in the simulated data before storing the simulated data in the training dataset. In either case, the simulated data stored in the training dataset reflects simulated sensor responses, if any, that are generated. The training dataset may identify an attribute (or attributes) of the physical system as a training target (or targets).

According to an implementation of the present disclosure, a non-transitory computer-readable storage medium tangibly embodying a computer readable program code is disclosed. The computer readable program code includes computer readable instructions that, when executed, causes a processor to carry out a method that includes computing sensor performance characteristics of a physical sensor used in measuring state variables (variant attributes) of a physical system and simulating, based on a process-based model, the physical system to produce simulated data corresponding to one or more physical state variables of the natural system. The processor applies to the simulated data, the computed sensor performance characteristics of the physical sensor to corrupt the simulated data to generate one or more simulated sensor responses that more closely approximates the actual output that would be produced by a physical sensor in an actual physical system corresponding to the one simulated. A training dataset is generated by the processor to train the machine learning model. The training data set includes the simulated data and at least some input parameters of the process-based model. At least one attribute of the physical system (e.g., at least one physical system property or at least one state variable) is identified in the training dataset as a training target. The training dataset may include several training examples, each training example associated with a respective training target and simulated data for the training target.

### Groundwater

According to an aspect of the present disclosure, a method describing an intelligent machine learning based computational modeling of vertical flux and other movement and storage properties of fluids in unsaturated porous medium such as groundwater flux through unsaturated soils, also referred to herein as a complex natural phenomenon is disclosed. The method uses sensor data as input. The method includes using a physical sensor to measure state variables (i.e., variant attributes) of a physical system such as water content of the physical system, the physical system being an unsaturated porous medium. The method also includes simulating, based on a process-based unsaturated groundwater flow model, the physical system to produce simulated data corresponding to one or more physical state variables of the natural system, to generate one or more simulated sensor responses that approximates an actual output of the physical sensor. A training dataset is generated to train a machine learning model. The training dataset is generated using the simulated data and identifies at least one attribute of the physical system as a training target. The training target can correspond to a boundary condition. The training target can correspond to a domain definition. The training target can correspond to a state variable that is unmeasurable by a physical sensor. The training target can be one of multiple training targets. Each of the multiple training targets may represent a different attribute of the physical system The process-based unsaturated groundwater flow model may be a virtual replica of the physical system that uses realistic data and/or other input data to mimic behavior of the physical system.

In one implementation, the method includes performing the simulating step and the applying step a number of times, each of the number of times corresponding to a scenario. Each scenario may be defined by a number of input parameters representing a domain definition, initial conditions, and/or boundary conditions of the physical system. For example, a domain definition may include a spatial distribution of numeric values of physical attributes that characterize a soil’s hydraulic behavior, initial conditions may include an initial spatial distribution of a soil water content, and a boundary condition may include a time varying water pressure or “head” specified at an upper surface of the soil. Another boundary condition may include a time varying flux of water from a vertical interval of soil representing plant root uptake from a root zone. Additional initial conditions and boundary conditions may be specified. A number of scenarios may be generated with each scenario corresponding to a simulation that produces a collection of simulated data and a collection of simulated sensor responses obtained by computationally emplacing a virtual sensor or a plurality of virtual sensors in the simulated domain. Each scenario may correspond to a training example stored in the training dataset. Each scenario may correspond to multiple training examples stored in the training dataset, where each training example represents a different period of time during the scenario. The machine learning model is trained based on at least the simulated sensor responses as training inputs.

According to an implementation of the present disclosure a computer program product is disclosed. The computer program product includes one or more computer-readable storage devices and program instructions stored on at least one of the one or more tangible storage devices, the program instructions executable by a processor, the program instructions including program instructions to intelligently model time-varying flow of a fluid through a porous medium. The computer program product includes program instructions to compute a response of sensor performance characteristics of a physical sensor used in measuring water-based variant attributes (state variables) of the porous medium. The computer program product also includes program instructions to simulate, based on a process-based unsaturated groundwater flow model, the physical system to produce simulated data corresponding to one or more physical state variables of the natural system. The computer program product includes program instructions to generate one or more simulated sensor responses that approximate an actual output of the physical sensor. The computer program product includes program instructions to generate a training dataset to train a machine learning model, as described herein.

### BRIEF DESCRIPTION OF THE DRAWINGS

The drawings are of illustrative implementations. They do not illustrate all implementations. Other implementations may be used in addition or instead. Details that may be apparent or unnecessary may be omitted to save space or for more effective illustration. Some implementations may be practiced with additional components or steps and/or without all of the components or steps that are illustrated. When the same numeral appears in different drawings, it refers to the same or like components or steps.

FIG. 1 depicts a block diagram of a data processing environment illustrating a network of data processing systems in which illustrative implementations may be implemented;

FIG. 2 depicts a block diagram of a data processing system in which illustrative implementations may be implemented;

FIG. 3 depicts a data synthesis configuration in which illustrative implementations may be implemented;

FIG. 4 depicts a machine learning engine in which illustrative implementations may be implemented;

FIG. 5 depicts a block diagram of an example training architecture for a model of a complex natural phenomenon in which illustrative implementations may be implemented;

FIG. 6 depicts a block diagram of a configuration for an intelligent computational model in which illustrative implementations may be implemented;

FIG. 7 depicts a block diagram of a tunnel detection configuration in which illustrative implementations may be implemented;

FIG. 8 illustrates a routine in which illustrative implementations may be implemented.

FIG. 9 depicts a data synthesis configuration in which illustrative implementations may be implemented;

FIG. 10 depicts a plot of simulated data of volumetric water content in which illustrative implementations may be implemented;

FIG. 11 depicts a block diagram of a vertical soil water flux estimation configuration in which illustrative implementations may be implemented;

FIG. 12 depicts a routine in which illustrative implementations may be implemented;

FIG. 13A depicts a first plot of predicted and true fluxes in accordance with an illustrative embodiment;

FIG. 13B depicts a second plot of predicted and true fluxes in accordance with an illustrative embodiment;

FIG. 13C depicts a third plot of predicted and true fluxes in accordance with an illustrative embodiment;

FIG. 13D depicts a fourth plot of predicted and true fluxes in accordance with an illustrative implementation.

### DETAILED DESCRIPTION

In the following detailed description, numerous specific details are set forth by way of examples in order to provide a thorough understanding of the relevant teachings. However, it should be apparent that the present teachings may be practiced without such details. In other instances, well-known methods, procedures, components, and/or circuitry have been described at a relatively high-level, without detail, in order to avoid unnecessarily obscuring aspects of the present teachings.

In machine learning, it is often impractical to obtain sufficient quantities of labeled training data via conventional physical observations. Insufficient quantities of labeled training data is a technical problem because the unavailability of an adequate quantity of training data negatively affects the quality of model predictions, i.e., results in a model that is unable to accurately generalize beyond the specific examples or combinations of input variables provided to it during training. A model that is unable to accurately generalize (a poorly generalizing model) will either be limited in its applicability (to an insufficiently broad range of variability of inputs) or be overfitted to the limited training data, such that it does not generalize well even within the range of input variability presented during training. This limits the ability to use data-hungry supervised machine learning techniques to predict, based on sensor data, the behavior of complex physical systems, particularly in the natural environment.

While data may be frequently synthesized for training machine learning models, a technical problem with synthesizing data for training, where it is important for the synthesized data to accurately reflect non-observable or difficult-to-observe variables of a physically determined system, is that data produced by physical systems rarely follow well-ordered parametric probability distributions, making the synthesizing of such data a highly complex undertaking. For example, because the data produced by physical systems rarely follows well-ordered parametric probability distributions, elementary sampling and stratification methods of obtaining training data frequently yields questionable results, negatively affecting the quality of the model predictions trained using such data.

For example, if a model is trained on sampling from well-ordered parametric probability distribution, such a model will perform poorly when it is used (i.e., in inference mode) with physical sensor data as input, because the physical sensor data reflects the imperfect and variable qualities of the physical sensors involved. Put another way, physical sensors potentially distort, in one or more ways, the physical reality of the physically-determined system in which the sensor is placed. The potential distortions are referred to herein as performance characteristics of the sensor or limiting characteristics of the sensor. A model trained on synthetic sensor data that does not reflect these limiting characteristics will not account for these characteristics, resulting in poor model output. Thus, a technical problem exists in not only obtaining sufficient training data, but ensuring that the training data reflects the complex, imperfect, and capricious qualities of the sensors involved, and/or to approximate measurements of the sensors involved, especially where collecting sufficient real-world measurement data to coax robust and accurate performance out of data-hungry machine learning algorithms may simply be impractical or impossible.

The illustrative implementations provide a technical solution to the insufficient quantity and inadequate quality of labeled training data to support a machine learning model of a physical process. More specifically, implementations relate to the generation and preparation of training data for applications that involve classification and regression in physical systems such as natural systems where the input to supervised machine learning models is sensor data. The illustrative implementations may synthesize large quantities of representative training data using a combination of one or more process-based models, as well as measured and synthesized inputs to the process-based models. The illustrative implementations modify theoretically perfect outputs of a process-based model to mimic the imperfection of real physical sensors by applying modifications. The modifications can include transfer functions and probabilistic representations of noise and bias obtained from characterizing actual sensor performance in response to known or controlled experimental conditions. The illustrative implementations may modify theoretically perfect outputs of a process-based model to approximate the corruption of physical information inherent in output from real physical sensors. A machine learning model is then trained using the modified outputs of the process-based model as inputs and/or training targets. A training target is a desired predicted output of the model being trained. In disclosed implementations, the training targets can represent attributes of the physical system such as domain definitions or variable conditions (state variables) used as inputs to the process-based model.

As discussed herein, a process-based model may be a simulation or mathematical description that depicts how a system or process behaves over time. The model may represent the processes that occur within a system, and how these processes interact with one another. The model may typically involve a set of equations or algorithms that describe the relationships between different model attributes, such as inputs, outputs, and internal states. The model may enable understanding, and prediction of the behavior of complex systems, such as weather patterns, soil systems, biological systems etc. The process-based model may be a combination of physics-based and/or empirical models.

A physics-based model may use the laws of physics to represent the physical processes that occur within a physical system. These models may be based on mathematical descriptions that represent the physical processes, such as conservation of mass and energy, Newton's laws of motion, the laws of thermodynamics, and the laws of electromagnetism. An empirical model however may be based on observations and measurements of a system, rather than on first principles or underlying physical laws. These models may employ statistical techniques to identify patterns and relationships within data, and can be used to make predictions about the future behavior of the system, or to understand how the system has behaved in the past. The process-based model, which may include a process-based unsaturated groundwater flow model, may also be a hybrid model which may be a combination of at least two of physics-based models, empirical models, and any other models. In one non-limiting example, an empirical model may be the Modified St. Venant model which relates the flow rate, water depth, and flow velocity in a river or open channel to channel geometry, bed slope, friction, and other factors affecting flow dynamics. In another non-limiting example, an empirical model may be the Penman-Monteith model which estimates (predicts) evapotranspiration from factors such as net radiation, air temperature, humidity, wind speed, and vegetation characteristics based on energy balance and aerodynamic concepts. An additional non-limiting example of an empirical model may be the Bishop, Sandberg, and Tong (BST) correlation used in nuclear power applications to predict the critical heat flux in nuclear fuel rods, which is the maximum heat flux that can be removed by boiling before a film of vapor forms on the rod's surface, leading to a rapid decrease in heat transfer efficiency. An example of an empirical model in the context of a soil water flux modeling (which may be a hybrid of physics-based and empirical modeling techniques) may be the Van Genuchten-Mualem equation which may be used to describe soil water characteristics. A physics-based model in this context may be the Richardson-Richards equation which may represent the movement of water in unsaturated soils.

In one non-limiting example, a physics-based model may be a numerical implementation of the Point Kinetics equations which are a set of first-order differential equations used in nuclear engineering to predict the time-dependent behavior of the neutron population in a nuclear reactor.

In a non-limiting example, a hybrid process-based model may be one that combines a physics-based numerical implementation of the Point Kinetics equations with physics-based flow equations such as the Navier-Stokes equations, and empirical heat transfer relations such as the Bishop, Sandberg, and Tong (BST) correlation, and other models and thermodynamic relations, to form a comprehensive model of a nuclear reactor and its electrical generation and cooling systems. Another non-limiting example of a hybrid process-based model may be the Variably Saturated Flow (VS2D/VS2DT) model developed by the United States Geological Survey (USGS) which uses the empirical Van Genuchten model to predict (estimate) variably saturated soil hydraulic properties and a numerical implementation of the physics-based Richardson-Richards equation to solve for unsaturated flow.

In one aspect, a method of generating training data for supervised learning about a physical system using a machine learning model may be disclosed. The method may comprise simulating the physical system using at least a set of input parameters and a process-based model that generates outputs corresponding to state variables. The physical system may be a natural system and the process-based model may be a virtual replica of the physical system that uses real world data such as such as sensor data and/or other input data such as domain definitions of the physical system, initial conditions of the physical system, boundary conditions of the physical system etc., to mimic the behavior of the physical system. The physical state variables may or may not be measurable by physical sensors. In an example method, a plurality of measurable outputs of the process-based models may be corrupted by the addition of uncertainty that is representative of imperfection inherent in the measurement of corresponding real state variables by real physical sensors. Uncertainty reflects an overall lack of precision and accuracy in measurements. Uncertainty may be represented by noise. Noise refers to random variability in data that cannot be attributed to any specific cause. Put another way, noise represents unpredictable fluctuations. Uncertainty may be represented by bias. Bias is a systematic error that skews results in a particular direction. Bias may occur due to assumptions or methodologies that consistently misrepresent the measurement. Uncertainty can reflect both noise and bias. In one aspect, the manipulation may capture the messiness, limitations or characteristics that a sensor may present during use rather than the messiness that a model fails to capture about the real world. Manipulation may thus replace one or more pure values of the process-based model outputs with one or more corresponding simulated sensor responses as would be measured by a virtual sensor having the same characteristics as the real physical sensor. Thus, the simulated data stored in the training dataset is understood to reflect the corresponding simulated sensor responses. The corrupted values are therefore a more real version of the pure values/model output. In another example method, a plurality of measurable outputs of the process-based unsaturated groundwater flow models may be modified or selected from the physical domain to generate or represent simulated sensor responses that approximate sensor data.

In the example methods the simulated sensor responses, which may be modified outputs of the process-based model or unmodified outputs, may be used as inputs to train a machine learning model, as discussed hereinafter. Inputs and/or outputs of the process-based model, such as time variant state attributes (state variables representing initial conditions, boundary conditions), time-invariant properties (domain definitions, static boundary conditions), synthetic sensor readings (e.g., state variables corrupted using sensor performance characteristics), etc., may be employed as training targets depending on the purpose of the model to be trained. In an implementation that uses an unsaturated groundwater flow model, different types of sensors may be used, including for example, water content sensors, temperature sensors, and pressure sensors (e.g., tensiometers).

In one training method, the machine learning model may be provided with realistically simulated output of sensors that measure properties or state variables of the physical system. Optionally, realistically simulated outputs may be combined with actual output of sensors for training. In another training method, the machine learning model may be provided with simulated output of sensors that measure properties or state variables of the physical system. Optionally, simulated outputs may be combined with actual output of sensors for training. Typically, state variables may represent time series (time-variant) data in a dynamic system. Put another way, state variables have values that fluctuate over time as the simulation (the process-based model) progresses. Properties may be time-invariant attributes of the natural physical domain or environment. Put another way, properties represent data that are invariant over time. For use of the trained machine learning model during inference, input data comprising actual sensor data such as previously unseen sensor data may be used to predict a state of one or more variables or one or more properties of the physical system.

In another aspect, the method of synthesizing data may be applicable to a range of architectures including a convolutional neural network (CNN), a Transformer neural network (TNN), a Visual Transformer (ViT) neural network, an Auto Encoder (AE, a form of CNN), a recurrent neural network (RNN) a long short-term memory network (LSTM, a form of RNN) as well as to non-ANN (non-artificial neural network) machine learning models and architectures, such as Random Forest (RF), other classification and regression tree (CART) methods, partial least squares regression (PLSR) gradient boosting regression, support vector regression (SVR) etc. Although descriptions provided herein may be beneficial in all supervised machine learning applications to natural physical systems where the input data comprises sensor data, the technique may be especially helpful for ANNs or RFs solving multi-target regression problems (predicting multiple targets simultaneously) because the process of synthesizing the input data may frequently involve process-based models in which a number of state variables are computed as part of the simulation process, and are thus available as outputs of the simulation that can be transformed into simulated sensor responses that provide physically consistent inputs and corresponding training targets which provide the proper inferential bias for multi-target prediction.

Certain operations are described as occurring at a certain component or location in an implementation. Such locality of operations is not intended to be limiting on the illustrative implementations. Any operation described herein as occurring at or performed by a particular component, can be implemented in such a manner that one component-specific function causes an operation to occur or be performed at another component, e.g., at a local or remote machine learning (ML) engine.

The illustrative implementations are described with respect to certain types of data, functions, algorithms, equations, model configurations, locations of implementations, additional data, devices, data processing systems, environments, components, and applications only as examples. Any specific manifestations of these and other similar artifacts are not intended to be limiting to the disclosure. Any suitable manifestation of these and other similar artifacts can be selected within the scope of the illustrative implementations.

Furthermore, the illustrative implementations may be implemented with respect to any type of data, data source, or access to a data source over a data network. Any type of data storage device may provide the data to an implementation of the disclosure, either locally at a data processing system or over a data network, within the scope of the disclosure. Where an implementation is described using a mobile device, any type of data storage device suitable for use with the mobile device may provide the data to such implementation, either locally at the mobile device or over a data network, within the scope of the illustrative implementations.

The illustrative implementations are described using specific code, designs, architectures, protocols, layouts, schematics, and tools only as examples and are not limiting to the illustrative implementations. Furthermore, the illustrative implementations are described in some instances using particular software, tools, and data processing environments only as an example for the clarity of the description. The illustrative implementations may be used in conjunction with other comparable or similarly purposed structures, systems, applications, or architectures. For example, other comparable mobile devices, structures, systems, applications, or architectures may be used in conjunction with such implementation of the disclosure within the scope of the disclosure. An illustrative implementation may be implemented in hardware, software, or a combination thereof.

The examples in this disclosure are used only for the clarity of the description and are not limiting to the illustrative implementations. Additional data, operations, actions, tasks, activities, and manipulations will be conceivable from this disclosure and the same are contemplated within the scope of the illustrative implementations.

Any advantages listed herein are only examples and are not intended to be limiting to the illustrative implementations. Additional or different advantages may be realized by specific illustrative implementations. Furthermore, a particular illustrative implementation may have some, all, or none of the advantages listed above.

### Example Architecture

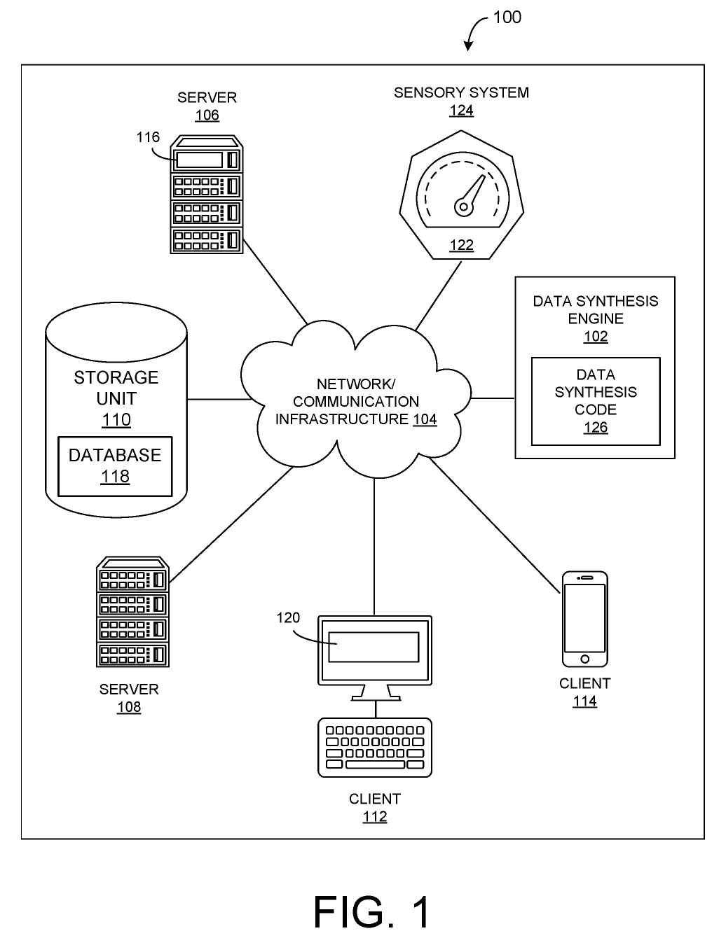

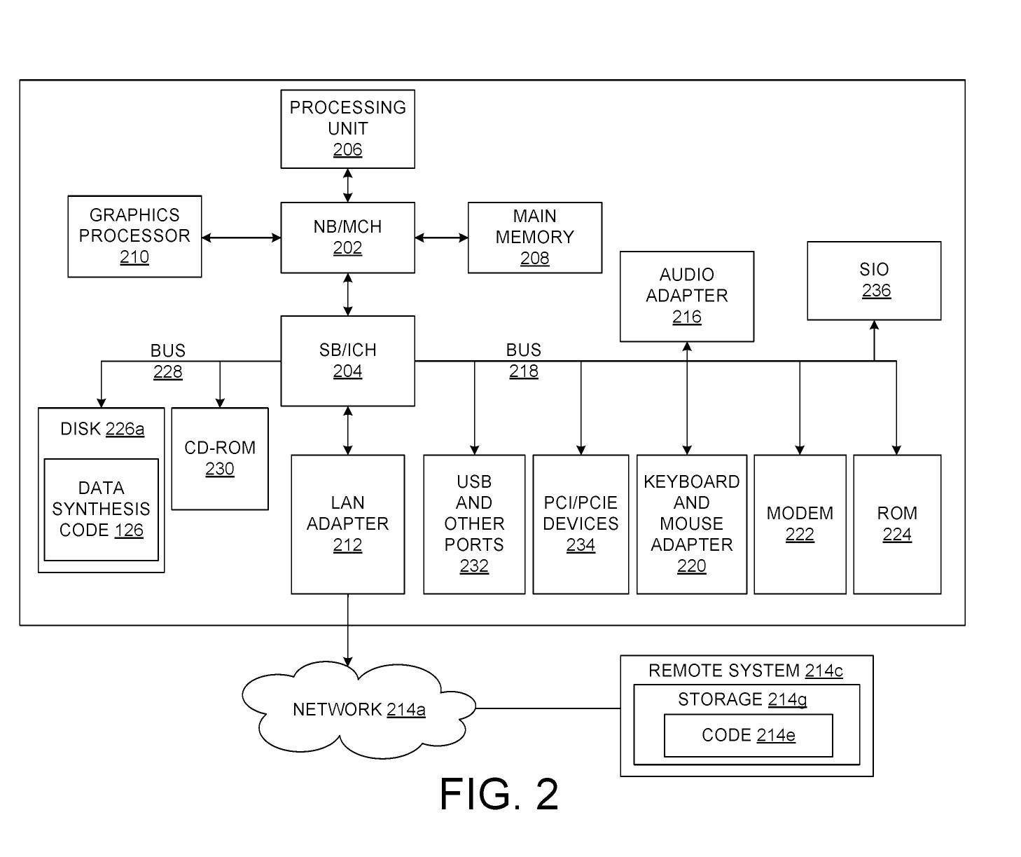

With reference to the figures and in particular with reference to FIG. 1 and FIG. 2, these figures are example diagrams of data processing environments in which illustrative implementations may be implemented. FIG. 1 and FIG. 2 are only examples and are not intended to assert or imply any limitation with regard to the environments in which different implementations may be implemented. A particular implementation may make many modifications to the depicted environments based on the following description.

FIG. 1 depicts a block diagram of a network of data processing systems in which illustrative implementations may be implemented. Data processing environment 100 is a network of computers in which the illustrative implementations may be implemented. Data processing environment 100 includes network/communication infrastructure 104. Network/communication infrastructure 104 is the medium used to provide communications links between various devices, databases and computers connected together within data processing environment 100. Network/communication infrastructure 104 may include connections, such as wire, wireless communication links, or fiber optic cables.

Clients or servers are only example roles of certain data processing systems connected to network/communication infrastructure 104 and are not intended to exclude other configurations or roles for these data processing systems. Server 106 and server 108 couple to network/communication infrastructure 104 along with storage unit 110. Software applications may execute on any computer in data processing environment 100. Client 112, client 114, are also coupled to network/communication infrastructure 104. Client 112 may be a remote computer with a display. Client 114 may be a mobile device configured with an application to send or receive information, such as to receive information from a server 106. A data processing system, such as server 106 or server 108, clients (client 112, client 114), data synthesis engine 102, sensory system 124 may contain data and may have software applications or software tools executing thereon.

Only as an example, and without implying any limitation to such architecture, FIG. 1 depicts certain components that are usable in an example implementation of an implementation. For example, servers and clients are only examples and do not imply a limitation to a client-server architecture. As another example, an implementation can be distributed across several data processing systems and a data network as shown, whereas another implementation can be implemented on a single data processing system within the scope of the illustrative implementations. Data processing systems (server 106, server 108, client 112, client 114, data synthesis engine 102, sensory system 124) also represent example nodes in a cluster, partitions, and other configurations suitable for implementing an implementation.

Data synthesis engine 102 may comprise configuration and code to simulate, based on a process-based model, a physical system and produce simulated data corresponding to one or more physical state variables of the physical system. In one example, the process-based model represents a saturated or an unsaturated (variably saturated) groundwater flow model. In another example, the process-based model represents a model of a vehicle suspension. In yet another example, the process-based model represents a soil breathing model. These examples are non-limiting and disclosed methods can be adapted to other process-based models. In some implementations, the engine may corrupt the simulated data by applying thereto computed sensor performance characteristics of a physical sensor to generate one or more simulated sensor responses that more closely approximates an actual output of the physical sensor. In some implementations, the engine may generate simulated sensor responses from the simulated data. In some implementations, the engine may generate the simulated sensor responses without manipulating the simulated data. The engine may further generate a training dataset to train the machine learning model, using the simulated data (including incorporating the simulated sensor responses) and the inputs and/or outputs (simulated data) of the process-based model as training targets. The engine may further use the trained machine learning model to predict unknown attributes of the physical system.

The sensory system 124 may comprise one or more physical sensors 122 and configuration to experimentally determine sensor performance characteristics which may comprise one or more combinations of experimentally determined sensor transfer functions, impulse response, sensitivity, selectivity, repeatability, uncertainty (noise and/or bias), and spatial weighting. Sensitivity is the minimum value or change in value of a physical quantity that a sensor is capable of detecting or resolving. For example, the minimum concentration of nitrate that an ion selective electrode could register represents the sensitivity of that sensor. Selectivity is the ability of a sensor to distinguish between two physical effects to which it may be sensitive. For example, if the above ion selective electrode also had some sensitivity to sulfate, that would represent a deficit of its selectivity for nitrate.

Sensor performance characteristics can be any quantitative representation of how accurately the sensor represents or fails to represent the physical reality. Put another way, sensor performance characteristics describe the sensor’s potential distortions of the physical reality of the physically determined system in which the sensor is placed. The sensor performance characteristics may be computed by characterizing physical sensor performance in response to one or more controlled experimental conditions to generate one or more transfer functions and probabilistic representations of a response of the physical sensor. One of more of the simulated data may then be corrupted by modifying the simulated data using the parametric descriptions of the transfer functions and probabilistic representations.

Client application 120, or any other application such as server application 116 implements an implementation described herein. Any of the applications can synthesize training data or use data from data synthesis engine 102 and to predict one or more physical state variables and/or physical system properties of the physical system. The applications can also obtain data from storage unit 110 for predictive analytics. In some implementations, the data may be stored in an indexable manner, such as in database 118. The applications can also execute in any of the data processing systems, such as server 106 or server 108, client 112, client 114, data synthesis engine 102, sensory system 124.

Server 106, server 108, storage unit 110, client 112, client 114, data synthesis engine 102, sensory system 124 may couple to network/communication infrastructure 104 using wired connections, wireless communication protocols, or other suitable data connectivity. Client 112, and client 114 may be, for example, mobile phones, personal computers or network computers.

In the depicted example, server 106 may provide data, such as boot files, operating system images, and applications to other data processing systems. Client 112 and client 114 may include their own data, boot files, operating system images, and applications. Data processing environment 100 may include additional servers, clients, and other devices that are not shown.

In the depicted example, data processing environment 100 may be the Internet. Network/communication infrastructure 104 may represent a collection of networks and gateways that use the Transmission Control Protocol/Internet Protocol (TCP/IP) and other protocols to communicate with one another. At the heart of the Internet is a backbone of data communication links between major nodes or host computers, including thousands of commercial, governmental, educational, and other computer systems that route data and messages. Of course, data processing environment 100 also may be implemented as a number of different types of networks, such as, for example, an intranet, a local area network (LAN), or a wide area network (WAN). FIG. 1 is intended as an example, and not as an architectural limitation for the different illustrative implementations.

Among other uses, data processing environment 100 may be used for implementing a client-server environment in which the illustrative implementations may be implemented. A client-server environment enables software applications and data to be distributed across a network such that an application functions by using the interactivity between a client data processing system and a server data processing system. Data processing environment 100 may also employ a service-oriented architecture where interoperable software components distributed across a network may be packaged together as coherent business applications. Data processing environment 100 may also take the form of a cloud and employ a cloud computing model of service delivery for enabling convenient, on-demand network access to a shared pool of configurable computing resources (e.g., networks, network bandwidth, servers, processing, memory, storage, applications, virtual machines, and services) that can be rapidly provisioned and released with minimal management effort or interaction with a provider of the service.

With reference to FIG. 2, this figure depicts a block diagram of a data processing system in which illustrative implementations may be implemented. Data processing system 200 is an example of a computer, such as server 106 or server 108, client 112, client 114, data synthesis engine 102, sensory system 124 in FIG. 1, or another type of device in which computer usable program code or instructions implementing the processes may be located for the illustrative implementations.

Data processing system 200 is described as a computer only as an example, without being limited thereto. Implementations in the form of other devices, in FIG. 1, may modify data processing system 200, such as by adding a touch interface, and even eliminate certain depicted components from data processing system 200 without departing from the general description of the operations and functions of data processing system 200 described herein.

In the depicted example, data processing system 200 employs a hub architecture including North Bridge and memory controller hub (NB/MCH) 202 and South Bridge and input/output (I/O) controller hub (SB/ICH) 204. Processing unit 206, main memory 208, and graphics processor 210 are coupled to North Bridge and memory controller hub (NB/MCH) 202. Processing unit 206 may contain one or more processors and may be implemented using one or more heterogeneous processor systems. Processing unit 206 may be a multi-core processor. Graphics processor 210 may be coupled to North Bridge and memory controller hub (NB/MCH) 202 through an accelerated graphics port (AGP) in certain implementations.

In the depicted example, local area network (LAN) adapter 212 is coupled to South Bridge and input/output (I/O) controller hub (SB/ICH) 204. Audio adapter 216, keyboard and mouse adapter 220, modem 222, read only memory (ROM) 224, universal serial bus (USB) and other ports 232, and PCI/PCIe devices 234 are coupled to South Bridge and input/output (I/O) controller hub (SB/ICH) 204 through bus 218. Hard disk drive (HDD) or solid-state drive (SSD) 226a and CD-ROM 230 are coupled to South Bridge and input/output (I/O) controller hub (SB/ICH) 204 through bus 228. PCI/PCIe devices 234 may include, for example, Ethernet adapters, add-in cards, and PC cards for notebook computers. PCI uses a card bus controller, while PCIe does not. Read only memory (ROM) 224 may be, for example, a flash binary input/output system (BIOS). Hard disk drive (HDD) or solid-state drive (SSD) 226a and CD-ROM 230 may use, for example, an integrated drive electronics (IDE), serial advanced technology attachment (SATA) interface, or variants such as external-SATA (eSATA) and micro- SATA (mSATA). A super I/O (SIO) device 236 may be coupled to South Bridge and input/output (I/O) controller hub (SB/ICH) 204 through bus 218.

Memories, such as main memory 208, read only memory (ROM) 224, or flash memory (not shown), are some examples of computer usable storage devices. Hard disk drive (HDD) or solid-state drive (SSD) 226a, CD-ROM 230, and other similarly usable devices are some examples of computer usable storage devices including a computer usable storage medium.

An operating system runs on processing unit 206. The operating system coordinates and provides control of various components within data processing system 200 in FIG. 2. The operating system may be a commercially available operating system for any type of computing platform, including but not limited to server systems, personal computers, and mobile devices. An object oriented or other type of programming system may operate in conjunction with the operating system and provide calls to the operating system from programs or applications executing on data processing system 200.

Instructions for the operating system, the object-oriented programming system, and applications or programs, such as server application 116 and client application 120 in FIG. 1, are located on storage devices, such as in the form of data synthesis code 126 on Hard disk drive (HDD) or solid-state drive (SSD) 226a, and may be loaded into at least one of one or more memories, such as main memory 208, for execution by processing unit 206. The processes of the illustrative implementations may be performed by processing unit 206 using computer implemented instructions, which may be located in a memory, such as, for example, main memory 208, read only memory (ROM) 224, or in one or more peripheral devices.

Furthermore, in one case, data synthesis code 126 may be downloaded over network 214a from remote system 214c, where code 214e is stored on a storage device 214g. In another case, data synthesis code 126 may be pushed over network 214a to remote system 214c, where code 214e is stored on a storage device 214g.

The hardware in FIG. 1 and FIG. 2 may vary depending on the implementation. Other internal hardware or peripheral devices, such as flash memory, equivalent non-volatile memory, or optical disk drives and the like, may be used in addition to or in place of the hardware depicted in FIG. 1 and FIG. 2. In addition, the processes of the illustrative implementations may be applied to a multiprocessor data processing system.

In some illustrative examples, data processing system 200 may be a personal digital assistant (PDA), which is generally configured with flash memory to provide non-volatile memory for storing operating system files and/or user-generated data. A bus system may comprise one or more buses, such as a system bus, an I/O bus, and a PCI bus. Of course, the bus system may be implemented using any type of communications fabric or architecture that provides for a transfer of data between different components or devices attached to the fabric or architecture.

A communications unit may include one or more devices used to transmit and receive data, such as a modem or a network adapter. A memory may be, for example, main memory 208 or a cache, such as the cache found in North Bridge and memory controller hub (NB/MCH) 202. A processing unit may include one or more processors or CPUs.

The depicted examples in FIG. 1 and FIG. 2 and above-described examples are not meant to imply architectural limitations. For example, data processing system 200 also may be a tablet computer, laptop computer, or telephone device in addition to taking the form of a mobile or wearable device.

Where a computer or data processing system is described as a virtual machine, a virtual device, or a virtual component, the virtual machine, virtual device, or the virtual component operates in the manner of data processing system 200 using virtualized manifestation of some or all components depicted in data processing system 200. For example, in a virtual machine, virtual device, or virtual component, processing unit 206 is manifested as a virtualized instance of all or some number of hardware processing units 206 available in a host data processing system, main memory 208 is manifested as a virtualized instance of all or some portion of main memory 208 that may be available in the host data processing system, and Hard disk drive (HDD) or solid-state drive (SSD) 226a is manifested as a virtualized instance of all or some portion of Hard disk drive (HDD) or solid-state drive (SSD) 226a that may be available in the host data processing system. The host data processing system in such cases is represented by data processing system 200.

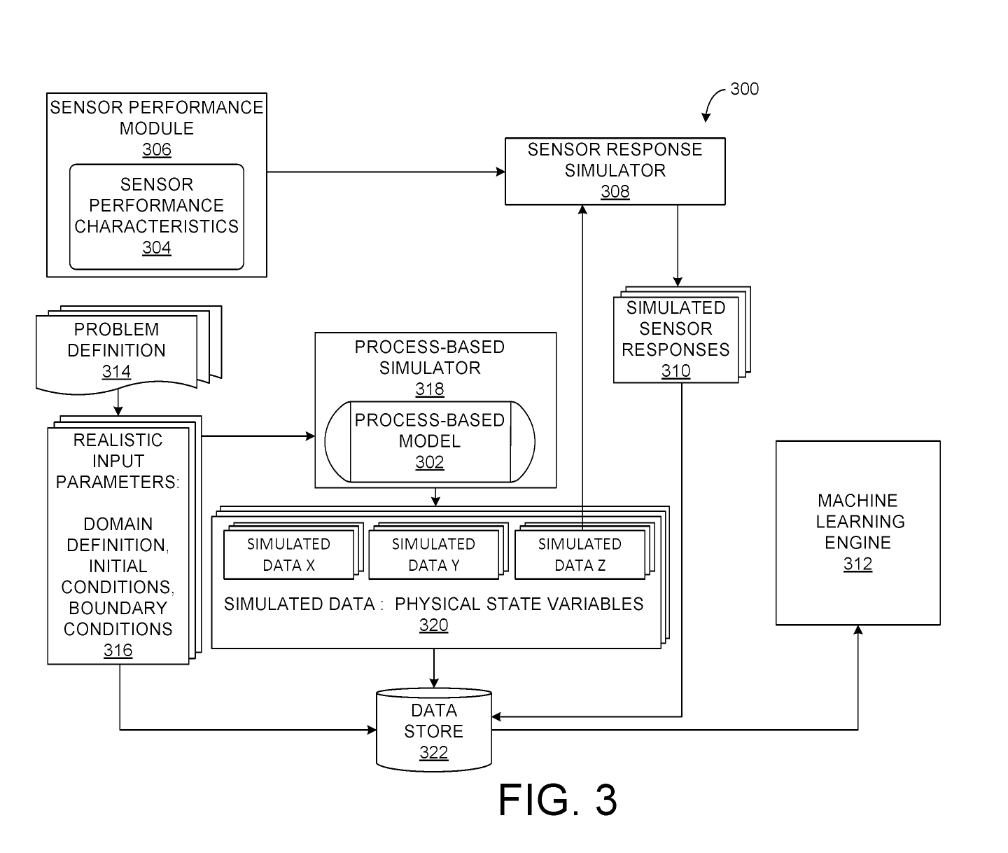

FIG. 3 discloses a data synthesis configuration 300 which may form a part of or be the data synthesis engine 102 of FIG. 1. Data synthesis configuration 300 may comprise a sensor performance module 306, a sensor response simulator 308, a process-based simulator 318, a machine learning engine 312, and a data store 322. The data synthesis configuration 300 may be used to synthesize training data and validation data and to carry out training and testing of a machine learning model. In one aspect, sensor performance module 306 may compute sensor performance characteristics 304 of a physical sensor 122 used in measuring state variables of a physical system. The process-based simulator 318 may be used to simulate, based on a process-based model 302, the physical system to produce simulated data 320 corresponding to one or more physical state variables of the physical system. In one aspect, the physical system may be a natural system. A natural system is a system that can be investigated using natural sciences and occurs in the natural world. These systems may range in size and can include systems that involve the motion of physical bodies, the transfer of heat, the behavior of materials and more, wherein various physics, chemistry, materials sciences, mathematical models, experiments, and observations may be used to comprehend how these systems operate and how their attributes vary over time and physical space. Examples may include the solar system, the atmosphere, the oceans, the weather, etc. In another aspect, the physical system is a man-altered natural system, a man-made system, or various combinations of natural, man-altered natural and man-made systems.

The computed sensor performance characteristics 304 of the physical sensor may be applied to one or more of the simulated data 320 to corrupt the simulated data to generate one or more simulated sensor responses 310 that may more closely reflect an actual output of the physical sensor 122. Responsive to generating sufficient simulated sensor responses 310 that may otherwise be impractical to generate in the real world (due to, for example, physical limitations, or lack of adequate number of physical sensors), the machine learning engine 312 may be engaged to train a machine learning model (not shown) based on the simulated sensor responses 310. The training input may comprise at least one or more of the simulated sensor responses 310 and the training targets may comprise one or more of the simulated data 320 and/or inputs of the process-based model 302. This may be helpful because the simulated sensor responses may be more readily obtainable in the real world for a specific location due to more readily representing real world sensor limitations and accumulated effects of surrounding space on an attribute being measured, though limited in breadth and use whereas the simulated data 320 and/or inputs of the process-based model 302 may be more useful, due to being a function of a specific time and/or space without unwanted noise/bias and other limitations from sensors and thus being more difficult to manually measure for a plurality of locations and/or time periods, or because the act of deploying one or more sensors to measure the training targets using sensors may alter the physical system in such a manner as to change its behavior, or because it may be impossible to measure the training targets such as no sensor exists capable of measuring them. Therefore, physical and natural systems may be accurately and/or precisely studied and attributes thereof measured via machine learning techniques described herein without the limitations posed by available and unavailable sensors with respect to the attribute being measured.

In one aspect, the process-based simulator 318 comprises one or more process-based models 302. A process-based model 302 may be a physics-based model, an empirical model or a combination of physics-based and empirical models. For example, in an example application concerning the soil breathing phenomena, the process-based model may be the Porous Media Flow Module of the COMSOL Multiphysics software model which includes functionality for modeling single-phase flow in porous media based on Darcy's law. Generally, models such as these and other models that are trusted and backed by extensive validation may be utilized.

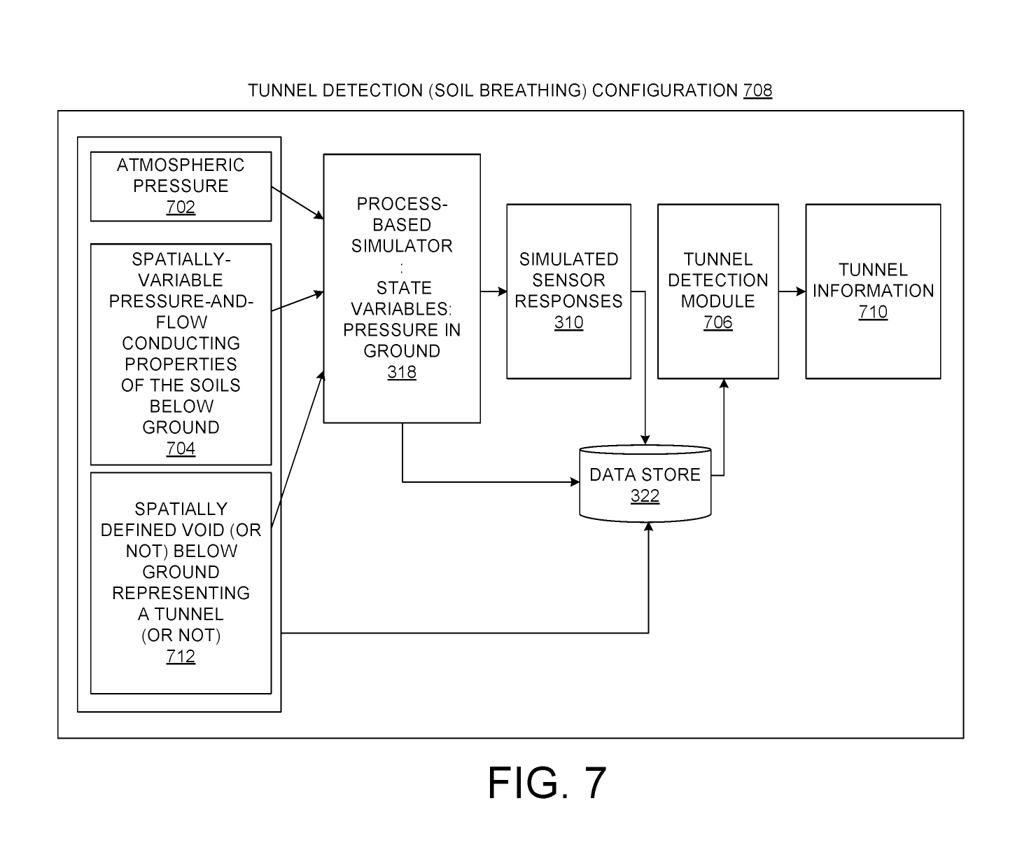

The process-based model 302 may receive data representing the independent variables used to predict a response of the physical system. The data may be realistic input parameters 316 for the physical system determined based on a definition of the problem (problem definition 314). Such data may include domain definitions of the physical system, initial conditions of the physical system and static or time-varying boundary conditions of the physical system. In an example of the soil breathing phenomena (tunnel detection, see FIG. 7), process-based model input data (realistic input parameters 316) may comprise spatially variable pressure-and-flow conducting properties of the soils below ground (although spatially variable, this attribute would not vary within a single simulation and could, therefore be considered an invariant attribute of the physical system for a specific simulation), depth to an impermeable boundary such as a water table, and the atmospheric pressure variation above ground that drives the subsurface response. These input data may be derived from time series of atmospheric pressure sensor measurements, field investigations of subsurface materials distributions, or synthetic realizations of either based on the character of observed natural variation. To produce realistic domain definitions, for example, several layers of soil, each having a separate mean air conductivity, may be represented. Further realism may be represented by using correlated random fields to add spatial variability to flow-related soil properties in the model domain as is often observed in the field. When specifying a correlated random field to represent variability in soil properties, different correlation lengths in the vertical and horizontal directions may be used to create more autocorrelation horizontally than vertically, as is typical in actual unconsolidated geologic deposits. In another example the response of a vehicle suspension to perturbation by crossing a speed bump can be modeled and an overloading state of the vehicle may be predicted based on detection of features of motion of the vehicle. In this example, realistic input parameters 316 for the physical system might be determined based on common design objectives for passenger vehicle suspensions, such as constraining the amplitude, period, and decay rate of pitch oscillations induced by road variability and driver inputs.

The output data of the process-based model 302 may be simulated data 320 that represents physical state variables of the physical system. The state variables may or may not be measurable in the physical system by the physical sensor 122. The immeasurable state variables may be immeasurable due to, for example, lack of an existing sensor capable of measuring the attribute. The measurable state variables may be measurable by the physical sensor but may be impractical to generate from the physical system due to, for example, physical limitations, or lack of an adequate number of physical sensors that can generate enough measurements for training a machine learning model, or because obtaining measurement by means of installing sensors or obtaining material samples would be impractical or so disruptive of the physical system as to alter the studied behavior of the physical system.

For example, simulated data X or Y of FIG. 3 may be immeasurable and may represent hidden or non-sensible variables of the physical system that one may ultimately want a machine learning model to predict or infer. Such data may be referred to as immeasurable simulated data or immeasurable state variables. For example, simulated data X may be the temperature of water in a river downstream of a nuclear power plant’s thermal discharge to the river had the power plant not exerted an influence, so that compliance with regulatory limits on induced temperature increase of the river can be assessed. In this example, the temperature increase due to the plant may be impossible to obtain by subtracting the river temperature without the plant operating from the river temperature with the plant operating because both temperatures cannot be obtained simultaneously at the point of compliance in the river; either the plant is operating or it is not. Simulated data X may thus represent additional training targets that may be used during training to provide inferential constraint. Simulated data Z on the other hand may be measurable and representative of, for example, the temperature of water exiting a cooling tower with existing sensors capable of measurement thereof. Simulated data Z may also be referred to as measurable simulated data or measurable state variables. However, in the case of simulated data Z, it may be impractical to measure or there may be physical limitations with measuring it such as the impracticality of measuring the volume of water lost through evaporation in a cooling tower, or the temperature of primary reactor cooling water entering the primary heat exchanger in an example of a nuclear power plant, because no temperature sensor can be practically maintained in the radioactive environment of the reactor and instead the temperature may be modeled using physical principles applied to knowledge of reactor operations. Further, until and unless subsequent limitations of the physical sensor are applied to simulated data Z, said data may be too pure and not representative of real measurements that the physical sensor 122 would actually report due to limitations or characteristics of the physical sensor 122. Thus, simulated data Z may be used by sensor response simulator 308 to generate, based on sensor performance characteristics 304, corresponding simulated sensor responses 310 that are more representative of measurements that would have been generated by the physical sensor 122.

Turning back to FIG. 3, sensor performance module 306 may be used to characterize the physical sensor 122 and establish the sensor performance characteristics 304 thereof. The sensor performance module 306 may enable experimental or computational determination of the sensor response characteristics by exposing the one or more physical sensors 122 to known controlled conditions and measuring the response thereof. From a collection of these measurements, statistical descriptions of sensor response characteristics such as sensitivity, selectivity, repeatability, uncertainty (noise and/or bias), and spatial weighting can be developed. Parametric descriptions of these sensor transfer functions may be used to modify the theoretically perfect process model outputs to mimic what a real sensor reports as the quantitative state of a system variable.

More generally, theoretically perfect output of the process-based model 302 may be obtained and, wherever an input or output state variable would be measured in the real world using physical sensor 122 as input to the ML model, the corresponding theoretical output of the process-based model may be corrupted to simulate the imperfections in the reported measurement that an actual physical sensor would introduce, whether they be due to transfer characteristics such as averaging times or effective interrogation volumes of the sensor, or due to uncertainty (noise and/or bias) inherent in transduction of physical properties into electrical signals. This may provide the needed “messiness” of the input data essential in making the machine learning solution robust to uncertainty, inaccuracy, and the degree of irreproducibility inherent in real-world input.

The value of a physical state variable reported by a sensor may deviate from the actual value of the corresponding state variable in the physical system, i.e., the truth, in several ways. Deviations of sensor readings from truth may include noise, bias including drift, and limitations on the ability of the sensor to precisely resolve in either or both space and time the attribute being measured.

Noise is a relatively high frequency variation about the long-term response of the sensor to a physical condition that is stable relative to the frequency of the noise. It is an unpredictable, i.e., random, residual that the sensor adds to its representation of the true value of the measured attribute and noise may or may not be self-correlated in time.

Bias is a relatively constant long-term residual between the central tendency, e.g., mean, median, or mode, of the noise-exhibiting sensor values and the actual value of the physical attribute being sensed. Bias can also change gradually over time. The amount that a bias changes over time is also called drift.

Limitations on resolution can be temporal and/or spatial. Limitations on temporal resolution typically manifest as the sensor exhibiting temporally lagging response to change in the state of the variable that it is measuring. For example, the thermal mass of a temperature sensor may limit the speed with which it can respond to a rapid change in the temperature of the environment it is measuring. Similarly, a scanning sensor technology may have a finite scan time associated with each reported value, such that measurements of the instantaneous state of a variable attribute such as a spectral reflectance are not instantaneously attainable.

A sensor whose spatial resolution is limited may respond to the attributes of a finite interrogation volume over which the sensor composites, integrates, or averages the value of the state variable that it reports. Compositing, integration, or averaging of the attributes within the interrogation volume by the sensor may occur with equal or spatially variable weighting of the spatial distribution of the attribute within the interrogation volume. For example, a volume of material whose moisture content affects the readings acquired by a dielectric based moisture sensor will be defined by the geometry of the electrical field induced in the material by the sensor in the process of obtaining the measurement. Due to diminishing field strength moving away from the sensor, the sensor value obtained will be more influenced by the contribution of material in immediate contact with the sensor than by the contribution of material farther away from the sensor but still within the electric field.

The way in which the sensor averages, integrates, composites, or otherwise combines variation in stimulus over a finite time into a single reading are the sensor’s temporal transfer characteristics. The way in which a sensor averages, integrates, composites, or otherwise combines spatial variation in properties within its interrogation volume into a single measurement are the sensor’s spatial transfer characteristics. Interplay may occur between the temporal transfer characteristics of a sensor and the spatial transfer characteristics of the sensor. A sensor’s transfer function is a mathematical model of the sensor’s temporal transfer and/or spatial transfer characteristics. A sensor may have both a temporal transfer function and a spatial transfer function, or the sensor may have a spatiotemporal transfer function.

A sensor’s temporal transfer function can be established by exposing the sensor to a step change over time in the state of the physical system attribute (state variable) the sensor is measuring. An example is to move a sensor suddenly from one environment to another, for instance from in air to in water, and observe the rate at which the sensor readings change in response to the step change. One mathematical model of the temporal transfer function of a sensor is defined by a time constant of the sensor response. A common definition of the time constant of a sensor is the time it takes the sensor output to reach the proportion (1-1/e) of an instantaneous change, i.e., a step change, in the state variable measured by the sensor.

A sensor’s spatial transfer function can be established by exposing the sensor to a step change in material attributes occurring at a series of discrete distances from the sensing element and recording the change in sensor output as a function of the distance to the material change. For example, a dielectric-based moisture sensor’s spatial transfer characteristics can be characterized be passing the sensing element through an interface formed by two fluids of contrasting dielectric permittivity such as methanol and vegetable oil, incrementally repositioning the sensor from a position of being fully surrounded by a first fluid to a position of being fully surrounded by a second fluid of a different dielectric permittivity than the first fluid. Since the sensor senses the dielectric of materials over a finite interrogation volume defined by the geometry of an electrical field emitted from the sensor element, as the distance between the sensing element and the fluid interface decreases the influence of the second fluid on the dielectric permittivity measured by the sensor increases until the sensor passes fully into the second fluid, at which point the dielectric permittivity of the second fluid dominates and the influence of the dielectric permittivity of the first fluid continues to diminish as the sensor is repositioned further and further from the fluid interface and into the second fluid. The spatial transfer function of the sensor can be defined as any mathematical function that suitably transposes the map of fluid dielectric permittivity versus sensor position to sensor response to fluid dielectric permittivity versus sensor position.

One method of establishing, i.e., empirically characterizing and modeling, the noise of a sensor is to expose the sensor to a controlled constant physical condition while acquiring repeated measurements from the sensor. The variability of the measurements about their mean will form a probability distribution that can be randomly sampled to simulate noise to add to a theoretically perfect simulated variable. For example, a dielectric sensor can be immersed in a bath of liquid of a known dielectric permittivity, and the sensor output can be repeatedly sampled. The mean of the samples is calculated and the residuals from the mean. Deviation of the temporal mean of the samples from the controlled value of the variable being measured by each sensor is the bias of that sensor. A probability distribution of potential sensor bias among a population of individual sensors that are each an instance of a given model of sensor can be defined by exposing a population of several identically manufactured sensors all to the same controlled state or same environment, and examining the variations in mean values resulting among the sensors. For example, one way of ascertaining the probability density function of bias of atmospheric pressure sensors is to place a plurality of pressure sensors all being of the same model in a room or chamber at stable pressure, averaging the multiple readings from each sensor, comparing across the averages of each sensor’s output to obtain a probability distribution of bias, and examining the residuals of each sensor’s measurements from its respective mean to obtain a probability distribution of noise. The probability distribution of the noise can be obtained from aggregating deviations from each sensor’s mean across all sensors or by aggregating the deviations of a subset of the sensors evaluated in the same environment or in different environments.

To simulate the effect of real sensor bias, a sensor-specific value drawn randomly from the distribution of biases once for each sensor is added to the process-based model output that in the physical world would be measured by the sensor. To simulate the effect of real sensor noise, for each simulated sensor measurement, a value drawn randomly from the distribution of sensor noise is added to each value of output generated by the process-based model that in the physical world would be measured by the sensor. Noise and bias are not mutually exclusive and both can be simultaneously simulated by adding both to the process-based model output. The probability distribution of bias can be Gaussian or any other parametric or non-parametric distribution that sufficiently describes the distribution of the empirically measured bias. The probability distribution of noise can be Gaussian or any other parametric or non-parametric distribution that sufficiently describes the distribution of the empirically measured noise, and/or the noise can be generated in a manner that is not completely random but is correlated in time with a degree of temporal correlation that matches or closely mimics the degree of temporal correlation observed in the empirically characterized noise.

A set of realistic input parameters 316 may correspond to a simulation run, also referred to as a scenario, and may be used to produce the simulated data 320 and simulated sensor responses 310. For example, if simulating soil breathing (a physical system) to obtain output that comprises soil gas pressures at numerous depths in a porous medium (physical state variables), a realistic input for the driving boundary condition at the medium surface can be a time series of actual atmospheric pressure measurements obtained from a weather monitoring station. In such a process-based model scenario, a realistic input for the transmissive properties of the medium and their spatial distribution within the model domain can be estimates (predictions) of soil porosity and soil permeability obtained by applying pedotransfer functions (PTFs) to profiles of material classification obtained from drilling logs produced by a geotechnical investigation. In a non-limiting example in which the physical system is a power generating plant coupled with cooling towers and a river as a thermal sink for plant cooling, realistic inputs to the process-based model might include the geometry of the river basin (a domain definition), historic records of river flow rate based on upstream gauging data (physical state variables), historic records of plant thermal power generation (physical state variables), and historic records of observed weather conditions that affect cooling tower performance (physical state variables). Such inputs may be combined in different ways from different periods of time to simulate a broad range of operating scenarios that would be impractical to accrue from direct experience only. The simulated data 320, simulated sensor responses 310 as well as realistic input parameters 316 for each scenario may form training examples in a synthetic dataset that may be stored in a data store 322. Each training example has at least one physical system attribute identified as a training target. In some implementations, one or more boundary conditions may be identified as the training target. In some implementations, a domain definition may be identified as the training target. In some implementations, one or more state variables may be identified as the training target(s). Each training example may represent a time series of state variables associated with the training target. In some implementations, a training example may represent an instance of a time series (e.g., a snapshot of the time series). In some implementations, a scenario may result in multiple training examples, each training example representing a period of time in the simulation scenario. In some implementations, each training example may represent a separate scenario (e.g., with different initial conditions/boundary conditions/sensor placement, etc.). The data store 322 may be sampled and used by machine learning engine 312. Upon obtaining an adequate ensemble of simulations, machine learning engine 312 may be engaged to train a machine learning model based on the synthetic dataset as discussed hereinafter.

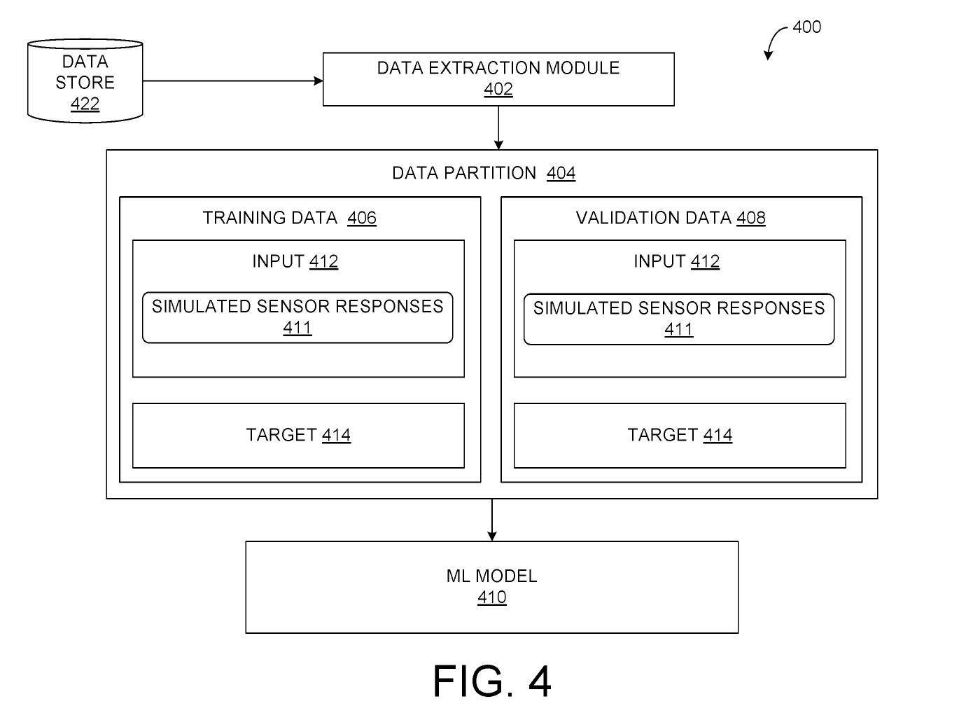

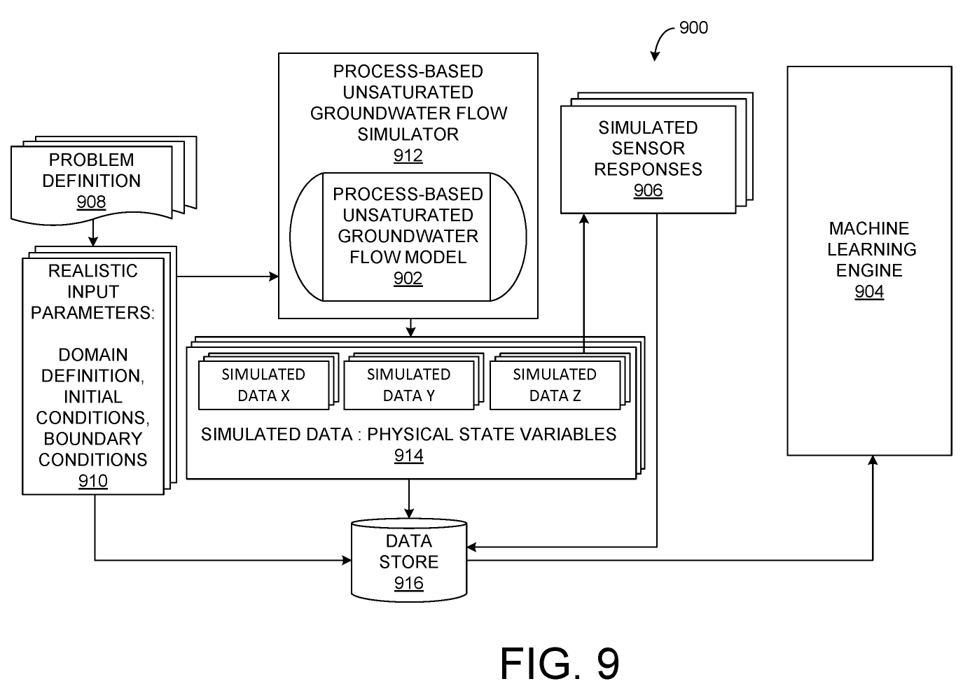

FIG. 4 shows a block diagram of a machine learning engine 400. The machine learning engine 400 may be an example of the machine learning engine 312 of FIG. 3 or the machine learning engine 904 of FIG. 9. The machine learning engine 400 may extract, by data extraction module 402, data from the synthetic dataset of data store 422 (e.g., of data store 322 or of data store 916), for use in training the ML model 410. The synthetic dataset may be a combination of inputs to the process-based model, pure outputs from the process-based model, and simulated sensor output responses from the sensor response simulator that forms the training, testing, and/or verification data set to be used in training one or more ML models 410. ML model 410 can be an example of machine learning engine 904 of FIG. 9. ML model 410 can be an example of machine learning engine 312 of FIG. 3. The trained ML models may make predictions or estimations, for example, of properties (domain definitions) or of physical state variables (e.g., initial conditions, boundary conditions) that are not measurable (or not measured) in the real world/physical system.

Data extraction module 402 may thus extract data, e.g., from data store 422 and partition the data into training data 406 and validation data 408. The training data 406 and the validation data 408 may be stored in data partition 404. In some implementations, at least some measurable simulated data may have been replaced with corresponding simulated sensor responses in the data store 422. In some implementations, the data extraction module 402 may replace at least some measurable simulated data with corresponding simulated sensor responses before partitioning the data. In either case, the training data set represented by data partition 404 reflects one or more of the simulated sensor responses 411 (e.g., simulated sensor responses 310 and/or simulated sensor responses 906). Thus, simulated sensor responses may be used as at least part of the input 412 (training or validation input). Training targets 414 may be identified in the training dataset represented by data partition 404. The training targets 414 may be any attribute of the physical system represented during the simulation. The training targets 414 may represent a physical system property, such as a domain definition or a static boundary condition. The training targets 414 may represent a physical state variable. The training targets 414 may represent a combination of physical state variables, i.e., a multi-target prediction. The training targets 414 may represent immeasurable simulated data. More generally, training data may be used to train the model, while validation data may be used to tune the machine learning model's hyperparameters and make decisions about the model's structure, such as selecting between different architectures. Further, test data may be used to evaluate the final performance of the machine learning model and to estimate its generalization ability to new, unseen data. Thus, a supervised machine learning model of any architecture that is sufficiently data-hungry to require not just more training data but also more diverse sensor training data than is practical and affordable to physically obtain in the real world can be developed and well maintained at exponentially cheaper and less time-consuming rates.

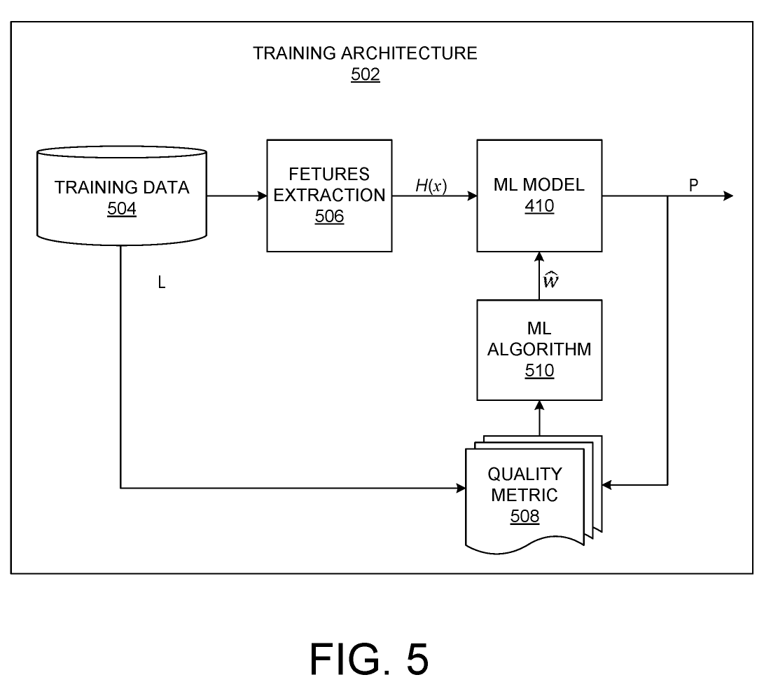

Turning now to FIG. 5, an example training architecture 502 is disclosed. The ML model may be a neural network ML model and may be trained using various types of training data sets. The training architecture 502 may be configured for machine-learning based recommendation generation in accordance with an illustrative implementation. Program code (such as data synthesis code 126) may extract various features 506 from training data 504. The training data 504 is an example of data included in data partition 404 of FIG. 4. The components of the training data 504 have labels L. The features are utilized to develop a predictor function, H(x) or a hypothesis, which the program code utilizes as an ML model 410. In identifying various features in the training data 504, the program code may utilize various techniques including, but not limited to, mutual information, which is an example of a method that can be utilized to identify features in an implementation. Other implementations may utilize varying techniques to select features, including but not limited to, principal component analysis, diffusion mapping, a Random Forest, and/or recursive feature elimination (a brute force approach to selecting features), to select the features. “P” is the output (e.g., flux, presence of a tunnel in the ground, etc.) that can be obtained, which when received, could further trigger the data processing environment 100 to perform other steps, such as steps of a stored instruction. The program code may utilize a machine learning ML algorithm 510 to train ML model 410, including providing weights for the outputs, so that the program code can prioritize various changes based on the predictor functions that comprise the ML model 410. The output can be evaluated by a quality metric 508.

By selecting a diverse set of training data 504, the program code trains ML model 410 to identify and weight various features of the physical system. To utilize the ML model 410, the program code obtains (or derives) input data or features to generate an array of at least one or more simulated sensor responses to input into input neurons of a neural network. Responsive to these inputs, the output neurons of the neural network produce an array that includes, for example, the time- and/or space-dependent attributes (physical state variables and/or physical system properties) of the physical system to be presented or used contemporaneously. Particularly, hidden or non-sensible attributes of the physical system may be of most use.

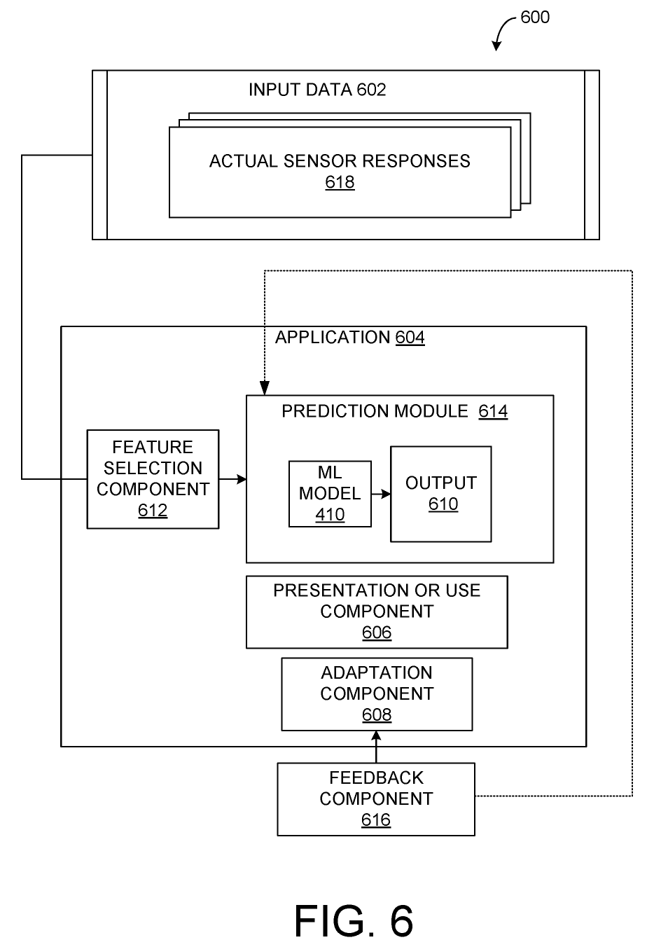

With reference to FIG. 6, this figure depicts a diagram of an example configuration 600 for intelligent machine learning based prediction of attributes of a physical or natural phenomenon that uses sensor data as input. Put another way, FIG. 6 depicts an example configuration 600 for using a ML model trained using disclosed techniques in an inference mode. The prediction can be implemented using application 604 in FIG. 6. Application 604 may be any application that relates to the attributes (physical state variables, properties) for which the ML model 410 was trained. Non-limiting and non-exhaustive examples of an application 604 include an application for analyzing saturated or unsaturated groundwater flow, an application for analyzing vehicle suspension, an application for analyzing soil breathing (e.g., tunnel detection), etc. Application 604 is an example of server application 116 or client application 120 in FIG. 1. The application 604 receives or monitors, for example in real time, a set of input data 602. The input data 602 is related to the purpose of application 604. The input data 602 may comprise actual sensor responses 618 such as actual pressure, actual flow rate through cooling system plumbing, actual upstream river temperature, actual volumetric water content of a soil column, etc. Due to the use of the actual physical sensor, sensor performance characteristics are already accounted for in the actual sensor responses 618. Put another way, there is no need to corrupt the actual sensor responses 618.

In one or more non limiting implementations, the configuration 600 includes feature selection component 612. Feature selection component 612 may be configured to drive feature selection of actual sensor responses 618. In particular implementations, feature selection component 612 may select, for example, a whole or part of the actual sensor responses 618. In another implementation, the system, e.g., feature selection component 612, may prioritize certain features over others. In another implementation, feature selection component 612 is configured to generate relevant features. The relevant features are features expected by the ML model 410. In some implementations, the relevant features may be based on the contents of a request from application 604. For example, the feature selection component 612 may separate out features from one or more of the actual sensor responses 618. This process of separating out features can be referred to as engineered feature extraction. For example, color saturation or hue may be extracted from an image because those features of the image may be more important to the problem addressed by the model. As another example, diurnal variation may be extracted from a time series of underground pressure. Put another way the feature selection component 612 may use feature extraction to reduce the raw sensor output to a feature or set of features used by the model. Thus, the feature selection component 612 may enable the prediction module 614 to use extractive features from sensor data (e.g., from actual sensor responses 618) rather than raw sensor data. Although illustrated as part of application 604, in some implementations the feature selection component 612 may operate on the actual sensor responses 618 before they are stored or provided as input data 602.

Using the extracted features and a trained ML model 410 that has been trained using a large number of different datasets (e.g., the datasets in data store 322 or data store 916), prediction module 614 determines model output 610, such as physical state variables and domain definitions. Output 610 represents any data item output by prediction module 614. Prediction module 614 may also thus predict one or more of physical state variables (representing initial conditions or boundary conditions) or domain definitions of the physical system. Boundary conditions may be time variant. Of course, these examples are not meant to be limiting and any combination of these and other examples are possible in view of the descriptions. As an example, the prediction module may be configured to predict at least one of the following: (a) unsaturated groundwater flux based on a time series sensor measurements of soil water content measurements at one or more depths; (b) unsaturated groundwater content based on time series sensor measurements of soil temperature at one or more depths; (c) unsaturated groundwater flux based on time series sensor measurements of soil temperature at one or more depths; (d) unsaturated groundwater pressure based on sensor measurements of soil water content at one or more depths; or (e) unsaturated groundwater pressure based on time series sensor measurements of soil temperature at one or more depths.

The prediction module 614 can be based, for example, on a neural network such as a CNN or RNN although it is not meant to be limiting. In an illustrative implementation, the model output 610 may be presented or used by a presentation or use component 606 of application 604. For example, the presentation or use component 606 may use the model output 610 to inform an action performed on the physical system. Non-limiting examples of the action performed on the physical system include controlling an irrigation system, providing an alert of a suspected presence of a tunnel, recording information related to an environmental regulation, etc. In some implementations, An adaptation component 608 may be optionally configured to receive input from a user to adapt the model output 610 (e.g., t state variables, domain definitions, conditions), if necessary. For example, changing a domain definition proposed by the prediction module 614 causes a recalculation of the output that takes the new domain definition into consideration.

Feedback component 616 optionally collects user feedback relative to the predicted model output 610. In one implementation, application 604 is configured not only to compute model output 610 (e.g., state variables, physical system properties) but also to provide a method for a user to input feedback, where the feedback is indicative of an accuracy of the prediction. Feedback component 616 applies the feedback in a machine learning technique, such as to ML model 410, in order to modify the ML model 410 for better predictions. In an illustrative implementation, the application 604 analyzes said feedback input and the application 604 reinforces the ML model 410 of the prediction module 614. If the feedback is satisfactory or unsatisfactory as to the accuracy of the predictions, the application strengthens or weakens parameters of the ML model 410 respectively. Put another way, the feedback may be used to further train, or refine, the ML model 410 to increase the quality of the model output in future predictions.

With reference to FIG. 7, this figure depicts a block diagram of an example configuration 708 for tunnel detection based on soil breathing analyses in accordance with an illustrative implementation. Configuration 708 is one non-limiting example of configuration 300 of FIG. 3. In the implementation, the trained ML model is configured to predict the tunnel information 710. Of course, this is one example implementation and is not meant to be limiting as other examples may be obtained in view of the descriptions herein. For example, process-based models for natural systems such as a river body, the sea, space/the sky/the atmosphere, or otherwise other natural systems may be obtained for computing time and/or space dependent attributes thereof for use in training a corresponding machine learning model. Process based models for physical systems may also be obtained accordingly.

Cross-border tunnels are a significant threat to national security that are proliferating as physical barriers and surveillance along national borders improve. Most cross-border tunnels have been discovered by human intelligence, because reliable detection of tunnels by technological means has previously proven elusive and prone to false positive results. The machine learning approach disclosed herein utilizes machine learning models trained to recognize the presence of a nearby tunnel from variations in subsurface pressure and overcomes deficiencies in other available technologies, such as active geophysical surveying and imaging techniques, and passive acoustic monitoring. Specifically, disclosed techniques generate training data that can be used to train a model to recognize the presence of a tunnel, or not, based on variations in subsurface pressure. This signal is not interfered with by non-tunnel activity (e.g., cultural noise). The effectiveness of using variations in subsurface pressure increases with increasing tunnel depth and requires very little communications bandwidth and computational power to collect and process. Moreover, such a model utilizes an infrastructure that is inexpensive to establish and maintain. The disclosed trained model can also self-adapt to geologic settings and does not require extensive pre-characterization of the local subsurface environment.

Tunnel detection (soil breathing) configuration 708 employs a model that directly relates pressure patterns in the ground to the tunnel information 710 by an intelligent sensor technology based on machine learning. A process-based model may receive model input data including, for example, spatially variable pressure-and-flow conducting attributes of the soils below ground 704 (parameter state values), spatially defined void (or not) below ground representing a tunnel (or not) 712 (domain definition) with atmospheric boundary conditions such as the atmospheric pressure 702 variation above ground that drives the subsurface response. These input data may be derived from time series of atmospheric pressure sensor measurements, field investigations of subsurface materials distributions, or synthetic realizations of either based on the character of observed natural variation. The implementation recognizes that air pressure in the ground may vary from one location to another and pressure in a first location M in the ground closer to the atmosphere may differ from pressure in a second location N below the first location. As depth increases, there may be less and less variation in pressures until a relaxation depth where essentially no detectable variation occurs. Should a tunnel be near the second location N, pressure in the tunnel may be closer to atmospheric pressure and this may affect the pressure of location N due to movement of air from the tunnel through the ground to location N. By feeding the pressures to the machine learning algorithm (tunnel detection module 706) one may predict tunnel information 710 such as whether there is one or more tunnels nearby or predict a distance from a tunnel as a regression, and/or the probability that there's a nearby tunnel.

In an implementation, virtual observation train/validation pairs may be generated from data store 322 by tunnel detection (soil breathing) configuration 708 using simulated sensor responses 310, and inputs and/or outputs of the process-based simulator 318. Inputs may include atmospheric pressure 702 and spatially variable pressure-and-flow conducting properties of the soils below ground 704. Because the spatially variable pressure-and-flow conducting properties would not change during a particular simulation, the pressure-and-flow conducting attributes may be considered properties (e.g. domain definitions) for the simulation. Other simulations may be run with different spatial distributions (a different domain definition). Pure uncorrupted outputs of the process-based simulator 318 (e.g., physical state variables in simulated data 320) may include, for example, pressure in the ground at various depths. Simulated sensor responses 310 may be generated using the simulated output, e.g., the pressures in the ground at various depths. The simulated sensor responses 310 may better match values that would be measured by actual physical sensors placed at various depths in the ground. Based on the virtual observation train/validation pairs, tunnel detection module 706 may be trained to predict the tunnel information 710.

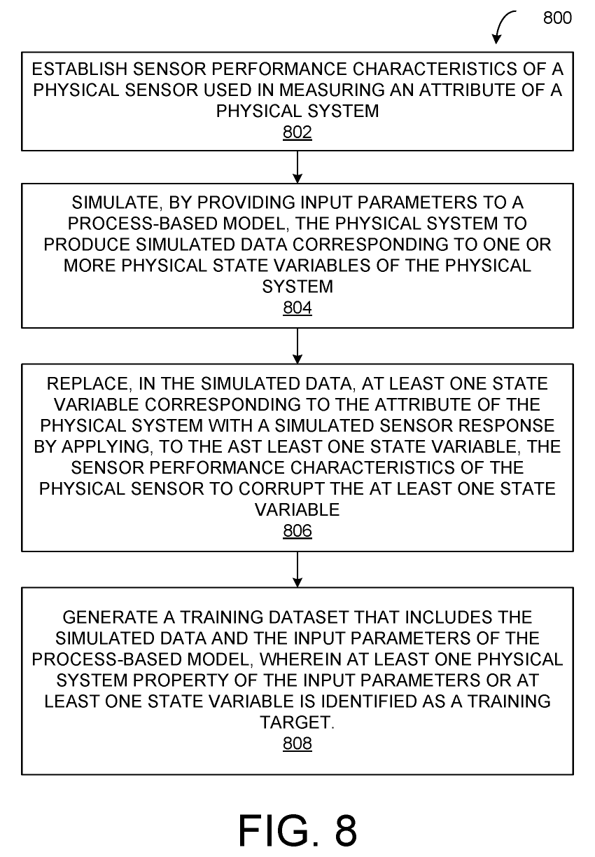

Turning now to FIG. 8, a routine 800 for modeling a complex natural phenomenon is disclosed. In the routine 800, data synthesis engine 102 experimentally determines or computes, in block 802, sensor performance characteristics of a physical sensor 122 used in measuring state variables (variable attributes) of a physical system. In block 804, data synthesis engine 102 simulates, based on a process-based model (such as model 302), the physical system to produce simulated data corresponding to one or more physical state variables of the physical system (e.g., simulated data 320). In block 806, data synthesis engine 102 applies, to the simulated data, the experimentally determined or computed sensor performance characteristics (e.g., sensor performance characteristics 304) of the physical sensor to corrupt the simulated data to generate one or more corresponding simulated sensor responses that more closely approximates the actual output the physical sensor would provide. Simulated sensor responses 310 are an example of such simulated sensor responses. In block 808, data synthesis engine 102 generates a training dataset to train the machine learning model, such as ML model 410 of FIG. 4. The training dataset may be generated from the simulated data, including (reflecting) simulated sensor responses. In some implementations, one or more state variables in the simulated data may be identified (used) as a training target. In some implementations, one or more attributes of the physical system, such as measurements obtained from actual physical sensors and/or human generated or human obtained inputs to the process-based model may be identified (used) as training targets. In some implementations, a training target may represent a time series of the attribute. In some implementations, each training target may be considered a training example.

In one aspect of the routine 800 the simulation of the simulated data and the applying of the sensor response characteristics to the simulated data is performed for a plurality of scenarios, where each scenario is defined by a plurality of input parameters representing a domain definition, initial conditions, and/or boundary conditions of the physical system. This creates a collection of simulated data and simulated sensor responses along with the corresponding input parameters that together form a synthetic dataset that can be used to train the machine learning model.

In one aspect of the routine 800, the computed sensor performance characteristics comprise a characteristic selected from the list consisting of experimentally determined sensor transfer functions, sensitivity, selectivity, repeatability, uncertainty (noise and/or bias), and spatial weighting. The computed sensor performance characteristics may be computed by characterizing physical sensor performance in response to one or more controlled experimental conditions to generate one or more transfer functions and probabilistic representations of a response of the physical sensor. The computed sensor performance characteristics may be used to manipulate the simulated data. For example, the simulated data may be corrupted by modifying the simulated data using parametric descriptions of the one or more transfer functions and probabilistic representations. More specifically, the simulated data may be corrupted by, first applying a transfer function to the simulated data that describes in mathematical terms the sensor’s sensitivity to media surrounding it which may or may not be homogeneous with respect to the attribute the sensor is measuring, thereby resulting in a sensor value that is not exactly the value of the sensed attribute of the medium at the exact location of the sensor, but rather a spatial average of values of the attribute in the medium proximal to the location of the sensor, and next adding a realization of sensor bias drawn from a probability distribution of the biases associated with several sensors and which remains unchanged for the specific sensor simulated, and further adding a realization of noise drawn from a probability distribution of noise exhibited by the specific model or type of sensor to each simulated data. This process derives a synthetic realization of sensor uncertainty.

In another aspect of the routine 800, the simulated sensor responses comprise physical attributes of state or mass transfer, which can include one or more of temperature, flow rate, pressure, concentration, measures of wave phenomena such as amplitude, frequency of audio, radio, light waves, etc.

In one aspect of the routine 800, the machine learning model is trained for multi-target prediction based on a plurality of simulated attributes representing physical state variables, wherein a subset of the plurality of simulated physical state variables are used as training targets to train the machine learning model for inference and the training loss function is formulated to penalize errors in estimation across the plurality of training targets.

In another aspect of the routine 800, the trained machine learning model is used in an inference mode to predict one or more actual variable attributes (physical state variables) of the physical system based on an input of one or more actual sensor responses. Further, the machine learning model and training method may also be engineered to predict one or more properties of the domain and initial and/or boundary conditions.

In another aspect of the routine 800, the output of the machine learning model may enable or be further be used in a practical application of measuring the time-and/or space dependent attributes (physical state variables) of physical or natural phenomena such as tunnels, power plants, rivers, and vehicle systems, which attributes are otherwise extremely difficult or impossible to measure in the real world with physical sensors, due to for example, (i) the lack of any commercially available or even viable sensors configured to accurately measure said attributes, (ii) the impracticality of measuring the physical state variables at multiple locations (e.g. thousands of locations) with available sensors or at locations that are difficult or impossible to reach (e.g. at certain depths below ground) with available sensors, and (iii) the time and computational expense that may be needed for otherwise manual solutions. For example, as a result of the prediction (the estimation of an attribute of the physical system), the routine 800 can include informing (e.g., initiating, providing, etc.) an action performed on the physical system. In some implementations, the action can be related to providing a user interface related to the prediction. For example, the action may include providing information related to an environmental regulation in a user interface, or providing an alert of a suspected tunnel, etc. The user interface can be used by management to take further action. In some implementations, the action can include performance of one or more additional aspects of the routine 800, such as initiating a remedial action as a result of a prediction. Therefore, said physical systems may be accurately and/or precisely studied and attributes thereof measured without the limitations posed by available and unavailable sensors with respect to the attribute being measured.

### Groundwater

Disclosed implementations can be used for quantifying soil water flux, which is important at least for understanding hydrobiogeochemical processes, irrigation scheduling and sustainable water use, climate monitoring & prediction, and regulatory applications. Past approaches have not provided practical solutions that can be used at scale. For example, weighing lysimeters is invasive, expensive, and maintenance intensive. As another example, heat pulse techniques are power hungry and present calibration challenges. As another example, capillary wicks need soil water characteristics and are maintenance intensive. Current techniques for volumetric water content time series don’t quantify through-flux or sinks, because water can flow without change in volumetric water content, sink terms (root water uptake and deep drainage) are not directly observable (i.e., not measurable by a physical sensor), and are missing the soil hydraulic behavior, a key physical system attribute. Implementations can be used to generate training data that enables a machine learning model to learn soil hydraulic behavior by watching the storage profile over time.

FIG. 9 discloses a data synthesis configuration 900 which may form a part of or be the data synthesis engine 102 of FIG. 1. Data synthesis configuration 900 may comprise a process-based unsaturated groundwater flow simulator 912, a machine learning engine 904, and a data store 916. The data synthesis configuration 900 may be used to synthesize training data and validation data and to carry out training and testing of a machine learning model. The process-based unsaturated groundwater flow simulator 912 may be used to simulate, based on a process-based unsaturated groundwater flow model 902, the physical system to produce simulated data 914 corresponding to one or more physical state variables of the physical system (an unsaturated porous medium). In one aspect, the physical system may be a natural system. A natural system is a system that can be investigated using natural sciences and occurs in the natural world. These systems may range in size and can include systems that involve the motion of physical bodies, the transfer of heat, the flow of fluids, the behavior of materials and more, wherein various physics, chemistry, materials sciences, mathematical models, experiments, and observations may be used to comprehend how these systems operate and how their attributes vary over time and physical space. Examples may include the solar system, soils, the atmosphere, the oceans, the weather, etc. In another aspect, the physical system is a man-altered natural system, a man-made system, or various combinations of natural, man-altered natural and manmade systems.

Responsive to generating sufficient simulated sensor responses 906 that may otherwise be impractical to generate in the real world (due to, for example, physical limitations, or lack of adequate number of physical sensors), the machine learning engine 904 may be engaged to train a machine learning model based on the simulated sensor responses 906. The training input may comprise at least one or more of the simulated sensor responses 906 and the training targets may comprise at least the simulated data 914 and/or inputs of the process-based unsaturated groundwater flow model 902.

In one aspect, the process-based unsaturated groundwater flow simulator 912 comprises one or more process-based unsaturated groundwater flow models 902. The process-based unsaturated groundwater flow model 902 may be a physics-based model, an empirical model or a combination of physics-based and empirical models. For example, in an example application to soil breathing phenomena, the process-based model may be a version of the groundwater flow model MODFLOW (modular three-dimensional finite-difference groundwater flow model) which solves the Darcy Equation, modified to model air flow dynamics instead of saturated groundwater flow. In another example of unsaturated groundwater flux, it may be the generally accepted HYDRUS (i.e., a hydrological model that analyzes water flow and solute transport in variably saturated media, for example, a “HYDRUS-1D” which simulates water, heat and solute movement in one-dimensional variably-saturated media) which solves the Richardson-Richards Equation. Yet another example of a subsurface flow model is the COMSOL Multiphysics Subsurface Flow Module. Generally, models that are trusted and backed by extensive validation may be utilized.

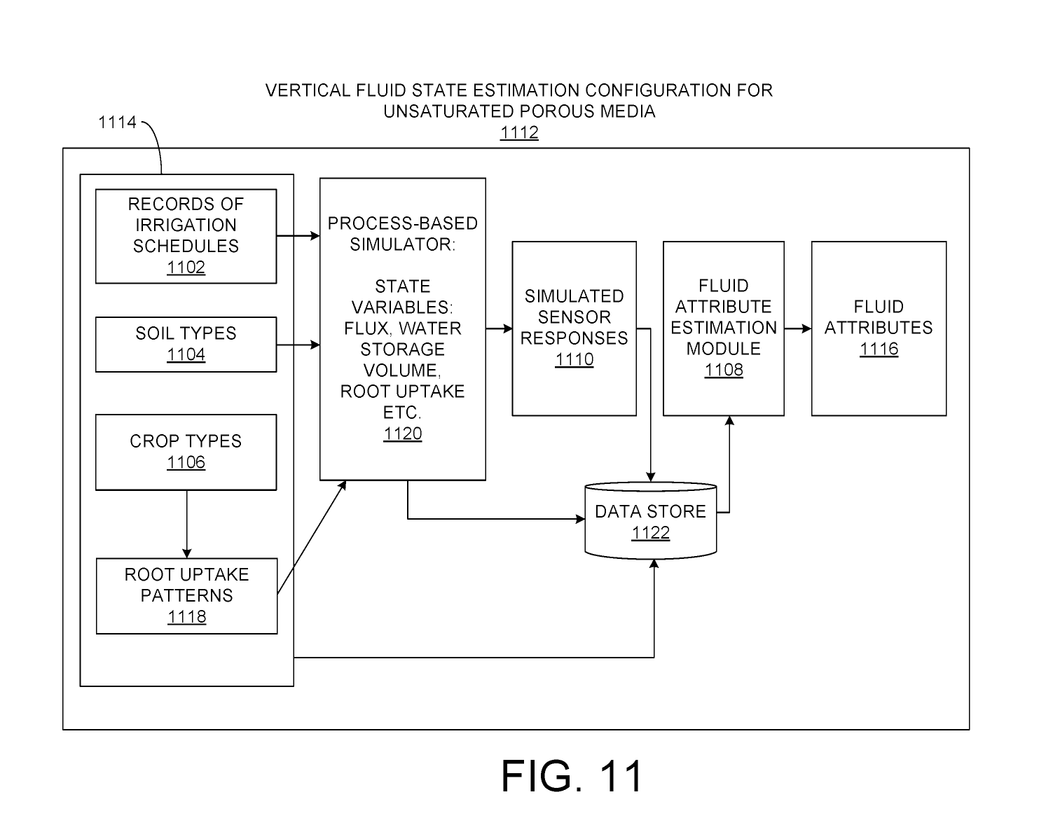

The process-based unsaturated groundwater flow model 902 may receive data representing the independent variables used to predict a response of the physical system. The data may be realistic input parameters 910 for the physical system determined based on a definition of the problem (problem definition 908). Such data may include domain definitions of the physical system, initial conditions of the physical system and static or time-varying boundary conditions of the physical system. For example, in a soil groundwater flux estimation problem, the input data to the process-based model may include, for example, a type of the soil and general records of irrigation schedules modified to realistically represent the natural physical system being simulated (See FIG. 11). More specifically, the input data may comprise various static vertical distributions of soil hydraulic properties obtained from the Natural Resources Conservation Service Soil Survey Geographic (NRCS SSURGO) database, from laboratory analysis of soil cores, from soil pits, or from in situ profiling sensor measurements; combined with various measured, interpolated, or synthesized temporally variable irrigation or precipitation patterns; further combined with crop root uptake data or crop definitions as input to complementary and integrated crop root uptake models in various user-defined rooting depth intervals. To produce realistic domain definitions, for example, several layers of soil each having a separate soil hydraulic properties may be represented. Further realism may be represented by using correlated random fields to add spatial variability to flow-related soil properties in the model domain as is often observed in the field. When specifying a correlated random field to represent variability in soil properties, different correlation lengths in the vertical and horizontal directions may be used to create more autocorrelation horizontally than vertically, as is typical in actual layered soil environments.

The output data of the process-based unsaturated groundwater flow model 902 may be simulated data 914 that represents time- and/or space-dependent attributes (physical state variables) of the physical system. The attributes may or may not be measurable in the physical system by the physical sensor 122. The immeasurable attributes may be immeasurable due to, for example, lack of an existing sensor capable of measuring the attribute. The measurable attributes may be measurable by the physical sensor but may be impractical to generate from the physical system due to, for example, physical limitations, or lack of an adequate number of physical sensors that can generate enough measurements for training a machine learning model, or because obtaining measurement by means of installing sensors or obtaining material samples would be so disruptive of the physical system as to alter the studied behavior of the physical system.

For example, simulated data X or Y of FIG. 9 may be immeasurable and may represent hidden or non-sensible attributes of the physical system that one may ultimately want a machine learning model to predict or infer. Such data may be referred to as immeasurable simulated data or immeasurable state variables. For example, simulated data X may be a volume flux of moisture passing through a unit volume of soil at a given time and a given location in the soil with no existing sensors capable of measurement thereof. Simulated data X may thus, represent additional training targets that may be used during training to provide inferential constraint, such as pore water matric potential, i.e., pressure. Simulated data Z on the other hand may be measurable and representative of, for example, a volumetric water content of a unit volume of soil in the physical system with existing sensors capable of measurement thereof. Simulated data Z may also be referred to as measurable simulated data or measurable state variables. However, in the case of simulated data Z, it may be impractical to measure or there may be physical limitations with measuring it such as the impracticality of measuring volumetric water content of a volume of soil at several depths and positions (e.g., hundreds or thousands of these).

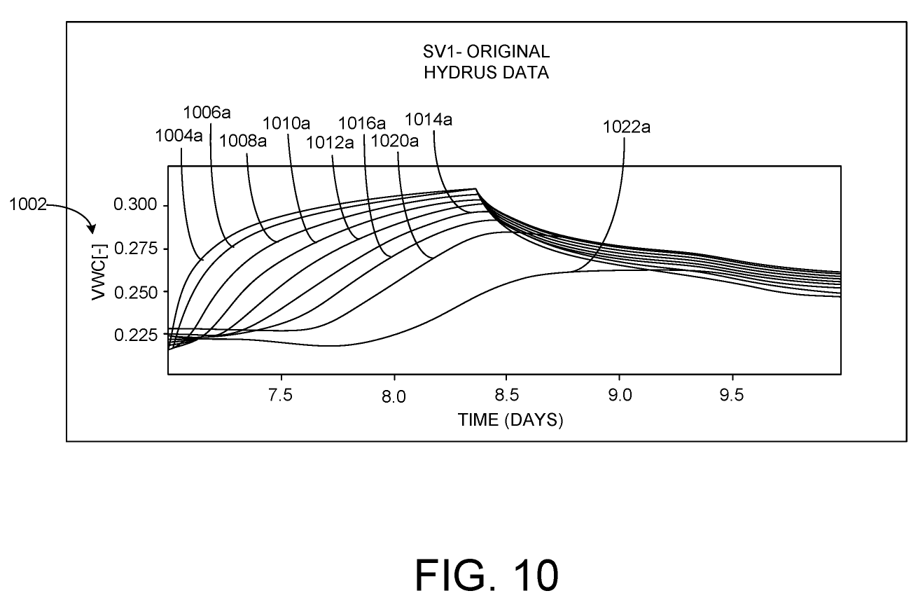

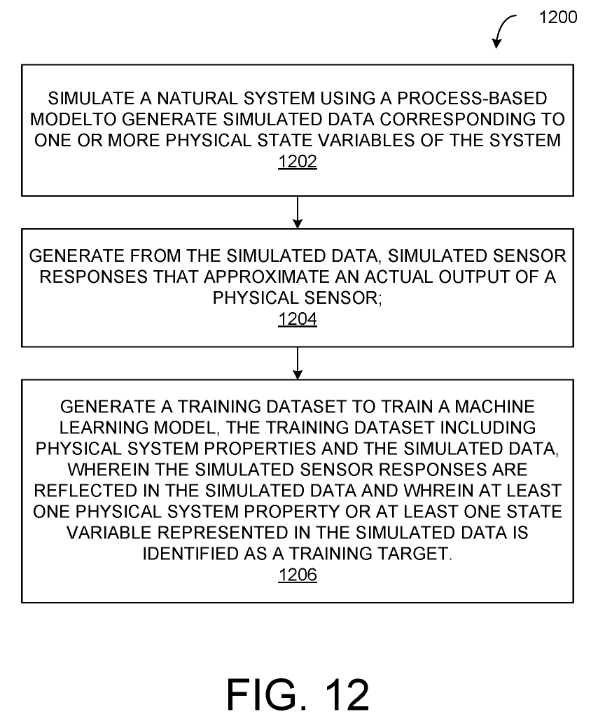

A plot illustrating an exemplary volumetric water content 1002 attribute as pure simulated data 914 using a HYDRUS process model is shown in FIG. 10. This may be transformed into one or more other simulated sensor responses that approximate actual sensor responses for use in training a machine learning model. This is an example output of a process-based model (e.g., output of 1202 of FIG. 12). In the example of FIG. 10, each trace on the plot represents a time series of the volumetric water content 1002 (VWC), a state variable, at a given depth in the soil throughout a portion of the simulation (e.g., a 45-day simulation). 1004a corresponds to a depth of 10-cm, 1006a corresponds to a depth of 20-cm, 1008a corresponds to a depth of 40-cm, etc., with 1022a corresponding to a depth of 90-cm. The simulated data of FIG. 10 has not yet been corrupted and thus represents theoretically perfect output, e.g., corresponding to the output of the process-based unsaturated groundwater flow model 902 of FIG. 9 and/or the state variables of process-based unsaturated groundwater flow simulator 1120 of FIG. 11. The example of FIG. 10 represents a time series of state variables (the volumetric water content at different depths at different instances of the time series). At the beginning of the time series, FIG. 10 illustrates, volumetric water content is low for all sensors and as water is applied (at later instances of the time series), the water reaches shallow depths (1004a) first and travels to deepest depths (1022a) last. Implementations can generate a training example using the entire time series, from portions of the time series, or from instances of the time series. The simulated data may be corrupted, as described herein, when used in the training example.

A set of realistic input parameters 910 may correspond to a simulation or scenario and may be used to produce the simulated data 914 and simulated sensor responses 906. An example of a realistic input to a process-based model of unsaturated groundwater infiltration and drainage can include irrigation scheduling records (e.g., as part of a domain definition). Another realistic input to a process-based model of unsaturated groundwater infiltration and drainage can be soil hydraulic properties (e.g., as part of a domain definition) obtained from SSURGO (Soil Survey Geographic Database) by cross-referencing United States Department of Agriculture Natural Resources Conservation Service (USDA NRCS) soil maps. The simulated data 914, simulated sensor responses 906 as well as realistic input parameters 910 for each scenario may be training examples in a synthetic dataset stored in a data store 916. Each training example has at least one physical system attribute identified as a training target. In some implementations, one or more boundary conditions may be identified as the training target. In some implementations, a domain definition may be identified as the training target. In some implementations, one or more state variables may be identified as the training target(s). Each training example may represent a time series of state variables associated with the training target. In some implementations, a scenario may result in multiple training examples, each training example representing a period of time in the simulation scenario. In some implementations, each training example may represent a separate scenario (e.g., with different initial conditions/boundary conditions/sensor placement, etc.). The data store 916 may be sampled and used by machine learning engine 904. Upon obtaining an adequate ensemble of simulations, machine learning engine 904 may be engaged to train a machine learning model based on the synthetic dataset as discussed hereinafter.

With reference to FIG. 11, this figure depicts a block diagram of an example configuration 1112 for fluid attribute estimation in unsaturated porous media such as vertical soil water estimation in the ground in accordance with an illustrative implementation. Configuration 1112 is a non-limiting example of configuration 300 of FIG. 3 In the example of FIG. 11, the trained ML model (for example, the fluid attribute estimation module 1108) is configured to predict a movement or rate of movement of fluids, such as water through soil, as fluid attributes 1116. The fluid attributes 1116 may be a collection of one or more extrinsic properties of fluid in porous media and attributes describing its movement and storage. The illustrative implementation recognizes that the movement of water through soil is more informative of soil intrinsic properties than the level of water saturation alone, which is an extrinsic property. The illustrative implementation recognizes that conventionally, there has been no means to directly measure fluid attributes, such as water flux, under real-world conditions. Groundwater flux is not a measurement that any operationally practical device exists to measure. Instead, groundwater flux has typically been investigated indirectly through complex mathematical models or by leveraging relationships between surrogate soil features and moisture. It is recognized that neither of these methods is a practical solution for applications that require flux estimates at high temporal resolution. Due to the ability of soils to conduct the flow of water without a proportional change in their stored water content, it is unreliable to equate flux directly to change in water content. Apart from estimating a flux state, other states of fluids (and similar matter) passing through an unsaturated porous medium, such as a storage state, a pressure state, a temperature state, and/or a nutrition state may be predicted as discussed herein. Accordingly, examples of important outputs of the fluid attribute estimation module 1108 that can be trained for prediction, individually or via multi-target prediction, and which may be outputs or inputs of the process-based unsaturated groundwater flow model 902 may include one or more combinations of: (i) a groundwater flux, (ii) storage, (iii) pressure, or (iv) nutrition, which are discussed in further detail hereinafter.

Groundwater flux may represent the volume per time of water passing by or through a vertical datum. Important instances of flux for informing management decisions and/or evaluating environmental impacts include: deep drainage flux (water flowing downward past the bottom of a root zone), infiltration (water entering the soil at the ground surface), root uptake ( flux out of the soil via plants over the depth interval corresponding to the root zone, and which can alternatively be computed as the difference between infiltration, deep drainage, and change in storage).

Water storage may be expressed in a plurality of ways including, volumetric water content (VWC) at one or more points in the unsaturated porous media, storage profile which is VWC as a function of depth; and length of storage which is VWC integrated over a depth interval, usually the depth interval corresponding to the root zone. Length of storage may be expressed in terms of feet or meters, (i.e., volume in acre-feet per unit surface area in acre, therefore “feet”).

Pressure (matric potential of water) may also be estimated by the fluid attribute estimation module 1108. Additional attributes may also be predicted (if modeled in the process-based modeling step) such as nutrition-related attributes including nutrient flux(es) and nutrient concentration(s). These may together form at least a part of possible fluid attributes 1116 as shown in FIG. 11.

Inputs to the fluid attribute estimation module 1108 that may be measured by sensors include any combination of VWC, pressure, temperature and other inputs as described herein. VWC at one or more discrete depths and at one or more points in time may be measured using, for example Time Domain Reflectometry (TDR), capacitance-based sensors, or other dielectric-based sensors. Pressure at one or more depths and at one or more points in time, also known as matric potential, as measured by a tensiometer may serve as input to the fluid attribute estimation module 1108. Even further, temperature at one or more depths and at one or more points in time, as measured by any variety of temperature sensors, including but not limited to thermistors, thermocouples and solid state temperature sensors may serve as input to the fluid attribute estimation module 1108 and the fluid attribute estimation module 1108 trained accordingly to predict fluid attributes 1116.

Additional inputs to a ML model may optionally include rainfall as a function of time, irrigation as a function of time, air temperature as a function of time, irrigation or precipitation water temperature as a function of time, solar insolation as a function of time (air temperature and solar insolation may affect plant root uptake which is a component in the mass balance affecting deep drainage and may therefore provide inferential bias in training the ML model when used as a training target in multi-target prediction).

Any one or more of the inputs listed above may alternatively be used as outputs in multi-target training of machine learning models to provide inferential bias to the training. Even if such variables will be measured in a real system of interest and therefore do not need to be predicted, and/or if estimations or predictions of such variables will not be directly useful in any subsequent action or decision that is based on the output of the machine learning model, their presence as an output while training the model may help improve the accuracy and performance of the model at estimating or predicting other output attributes upon which actions or decisions may be based.

Some examples of process-based models that can be used to simulate the flow (e.g., flux) and storage of groundwater in the unsaturated (i.e., vadose) zone of soil, and may also be used to simulate the moisture-coupled transport of heat and/or chemical constituents (e.g., nutrients) depending on modules installed and invoked, include HYDRUS-1D, HYDRUS-3D, MODFLOW Unsaturated Zone Flow Package (UZF1) and COMSOL Multiphysics Porous Media Flow Module. The terms “HYDRUS”, “HYDRUS-1D”, “HYDRUS-3D”, “MODFLOW”, and “COMSOL Multiphysics” may be subject to trademark rights in various jurisdictions throughout the world and are used here only in reference to the products or services properly denominated by the marks to the extent that such trademark rights may exist.

A hypothesis for generating the vertical fluid attribute estimation configuration 1112 for unsaturated porous media, shown in FIG. 11, is that soil hydraulic properties may be inferred implicitly with machine learning based on observed vertical fluid distributions through time in response to surface wetting events of different intensity and duration. Another hypothesis is that infiltration and deep drainage may be inferred accurately over a range of soils without soil-specific hydraulic properties provided and that this forms the basis for estimating root uptake. It is recognized that this presents a complex, high degree-of-freedom problem and methods described herein may be used to provide a generalized solution.

Virtual observation train/validation pairs may be generated from data store 1122 by vertical fluid attribute estimation configuration 1112 for unsaturated porous media using simulated sensor responses 1110, and inputs and/or outputs 1114 of the process-based unsaturated groundwater flow simulator 1120. Inputs may include, for example, records of irrigation schedules 1102, soil types 1104, crop types 1106 and root uptake patterns 1118. The records of irrigation schedules 1102, soil types 1104, crop types 1106 and root uptake patterns 1118 are examples of realistic input parameters 910. Based on the virtual observation train/validation pairs, fluid attribute estimation module 1108 may be trained to predict fluid attributes 1116.

In a specific experimental test, virtual observation train/validation pairs were generated for approximately 1,350 different soil types, fully representative of the United States Department of Agriculture's (USDA’s) soil texture triangle, using an industry standard, physics-based unsaturated soil flow code (HYDRUS-1D) as the process-based model. Data was generated under a variety of surface boundary conditions. The dataset introduced as input to the ML algorithm consisted of volumetric water content at multiple depth increments to a depth of 1 meter, and its temporal and spatial gradients. Pre-calculating the gradients was found to add important information for inferring flux, significantly improving performance. Water content measurements were assumed to be made at intervals of 1 centimeter in depth and 1 minute in time. Five neural network architectures were tested with all neural networks being optimized using Bayesian hyperparameter optimization using the Gaussian Process. Configuration and fine-tuning of the hyperparameters was accomplished through Bayesian optimization. The results of the rootless surface flux (5-cm depth) estimative neural network with a single target showed the models being able to adeptly capture the flux profiles over the 1-minute time resolution for various soils. The models achieved a coefficient of determination of 0.82. Use of a multi-task model increased the coefficient of determination to an impressive 0.88. These results supported the project hypotheses that ML-based analysis of water content profiles through time can support flux estimation with no need for soil specific information or knowledge of surface boundary conditions.

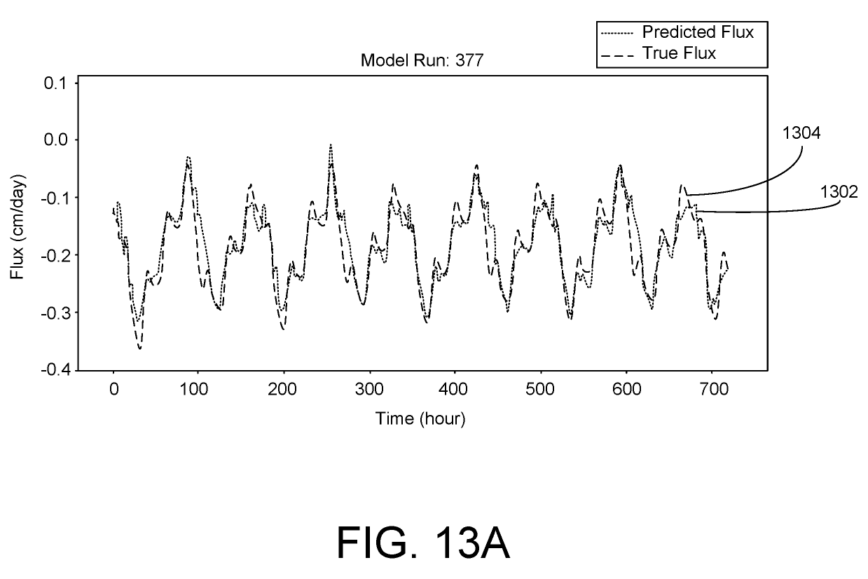

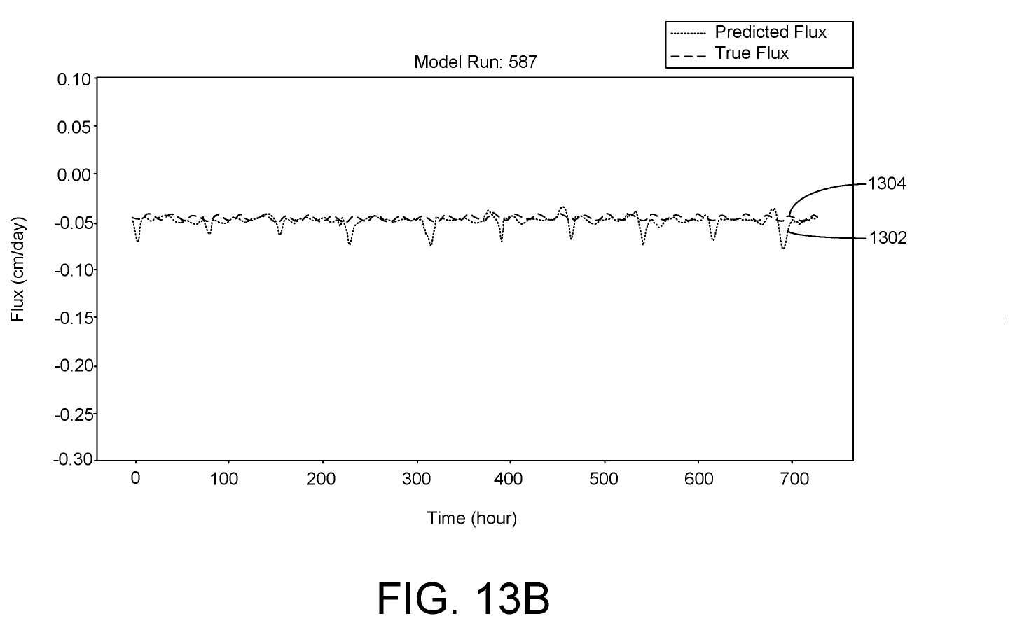

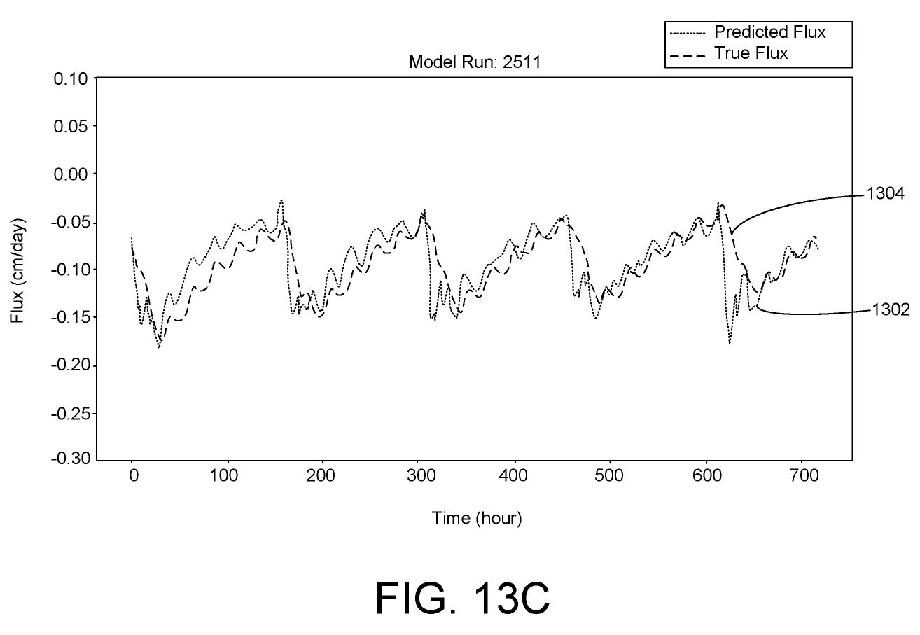

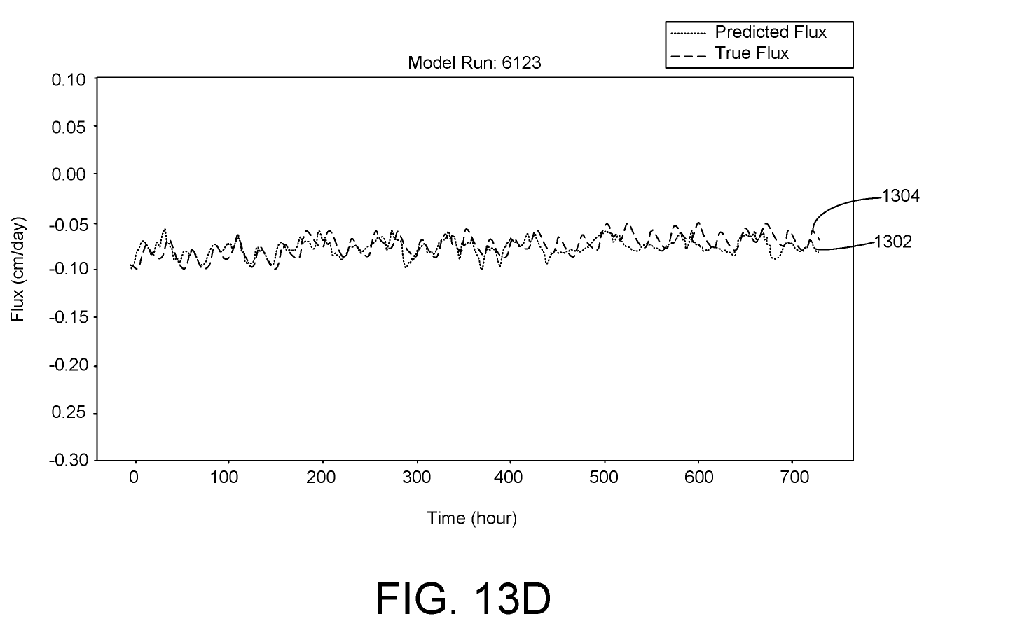

In another specific experimental test, virtual observation train/validation pairs were generated for approximately 45,000 different physical scenarios involving all soils listed in the US Department of Agriculture (USDA) SSURGO database for Fresno, King, and Tulare Counties in California associated with California almond orchards. Diurnally and seasonally variable root uptake was modeled by HYDRUS-1D using modeled reference evapotranspiration demand and published Feddes parameters to account for the effects of soil water potential, and the time-varying surface boundary condition was specified by adopting the almond irrigation recommendations of the University of California Cooperative Extension for Kern County with variability about the recommendations applied to different scenarios. Each model in the ensemble simulated unsaturated groundwater dynamics for a period of 56 days of which the final 28 days were used to simulate the sensor response of several commercially available multi-level VWC sensors based on prior laboratory characterization of the noise, bias, and temporospatial transfer characteristics of each sensor type in response to controlled laboratory conditions. Commercial sensors included the SoilVUE10 (Campbell Scientific, Logan, UT), Drill and Drop (Sentek, Australia), and EnviroScan (Sentek, Australia). The terms SoilVUE10, Drill and Drop, and EnviroScan may be subject to trademark rights in various jurisdictions throughout the world and are used here only in reference to the products or services properly denominated by the marks to the extent that such trademark rights may exist. The training/validation datasets resulting from simulation of each model of commercial probe were used to optimize the hyperparameters and train separate LSTM models to predict as output the instantaneous vertical groundwater flux across the 120-cm deep vertical datum also known as deep drainage from input comprising the prior twenty-four hourly measurements of VWC at each depth supported by the respective sensor model. The LSTM models achieved impressive performance, exhibiting for example a coefficient of determination of 0.91 for the model trained to use EnviroScan data as input. See FIG. 13A- 13D which illustrate four plots of output predicted fluxes 1302 (i.e., deep draining – flux at 120-cm deep) of a machine learning model in comparison with respective true fluxes 1304 using Sentek EnviroScan sensor as the simulated sensor forming input to the LSTM. These figures demonstrate the accuracy with which a model trained using disclosed techniques. The true flux 1304 was determined in a very limited, controlled environment. There is no way to practically measure flux in a real-world setting.

Thus, by the configuration of FIG. 11, a method/system is disclosed for estimating fluid attributes 1116 from a time series of soil water or fluid content measurements in a vertical profile. Further the machine learning model / fluid attribute estimation module 1108 is used not necessarily to predict soil hydraulic properties as an endpoint to merely replace conventional iterative forward model inversion, but rather to infer soil hydraulic behavior internally, unconstrained by the approximations and assumptions necessarily inherent in the derivation of “governing equations”. This more holistically overcomes some of the documented and most elusive limitations of conventional methods of modeling subsurface hydraulic phenomena.

Turning now to FIG. 12, a routine 1200 for modeling a complex natural phenomenon is disclosed. In block 1202, data synthesis engine 102 simulates, based on a process-based unsaturated groundwater flow model 902, the physical system, which is an unsaturated porous medium, to produce simulated data corresponding to one or more physical state variables of the physical system. In block 1204, data synthesis engine 102 generates one or more corresponding simulated sensor responses that approximate the actual output the physical sensor would provide. In block 1206, data synthesis engine 102 generates a training dataset to train the machine learning model, the training dataset being generated using the simulated sensor responses as training inputs and the simulated data, measurements obtained from actual physical sensors and/or human generated or human obtained inputs to the process-based model as training targets.

In one aspect of the routine 1200 the simulation of the simulated data and simulated sensor responses are performed for a plurality of scenarios, where each scenario is defined by a plurality of input parameters representing a domain definition, initial conditions, and/or boundary conditions of the physical system. This creates a collection of simulated data and simulated sensor responses along with the corresponding input parameters that together form a synthetic dataset that can be used to train the machine learning model.

In one aspect of the routine 1200, the machine learning model is trained for multi-target prediction based on a plurality of simulated time- and/or space-dependent attributes (physical state variables), wherein a subset of the plurality of simulated time- and/or space-dependent physical state variables are used as training targets to train the machine learning model for inference and the training loss function is formulated to penalize errors in estimation across the plurality of training targets.

In another aspect of the routine 1200, the trained machine learning model is used in an inference mode to predict one or more actual time- and/or space-dependent (variable) attributes (i.e., physical state variables) of the physical system based on an input of one or more actual sensor responses. Further, the machine learning model and training method may also be engineered to predict (estimate) one or more properties of the domain (e.g., properties of the soil below ground) and initial and/or boundary conditions. For example, in flux estimation, irrigation schedule may be predicted (i.e., an attribute of the physical system may be estimated) based on the same inputs used to predict deep drainage. As another example, the machine learning model may predict a spatial distribution of soil permeability. As another example, the machine learning model may predict (estimate) a pattern of water applied in an irrigation system. As another example, the machine learning model may predict a pattern of surface infiltration.

In another aspect of the routine 1200, the output of the machine learning model may enable or be further be used in a practical application of measuring the time-and/or space dependent attributes (physical state variables) of an unsaturated porous media, which attributes are otherwise extremely difficult or impossible to measure in the real world with physical sensors, due to for example, (i) the lack of any commercially available or even viable sensors configured to accurately measure said attributes, (ii) the impracticality of measuring the physical state variables at multiple locations (e.g. thousands of locations) with available sensors or at locations that are difficult or impossible to reach (e.g. at certain depths below ground) with available sensors, and (iii) the time and computational expense that may be needed for otherwise manual solutions. For example, as a result of the prediction (the estimation of an attribute of the physical system), the routine 1200 can include informing (e.g., initiating, providing, etc.) an action performed on the physical system. In some implementations, the action can be related to providing a user interface related to the prediction. For example, the action may include providing an irrigation schedule in a user interface or providing information related to an environmental regulation in a user interface, etc. In some implementations, the action can include performing one or more additional aspects of the routine 1200, such as controlling an irrigation system. Therefore, an unsaturated porous medium such as soils may be accurately and/or precisely studied and attributes thereof measured in agricultural applications without the limitations posed by available and unavailable sensors with respect to the attribute being measured.

The descriptions of the various implementations of the present teachings have been presented for purposes of illustration but are not intended to be exhaustive or limited to the implementations disclosed. Many modifications and variations will be apparent to those of ordinary skill in the art without departing from the scope and spirit of the described implementations. The terminology used herein was chosen to best explain the principles of the implementations, the practical application or technical improvement over technologies found in the marketplace, or to enable others of ordinary skill in the art to understand the implementations disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

The components, steps, features, objects, benefits and advantages that have been discussed herein are merely illustrative. None of them, nor the discussions relating to them, are intended to limit the scope of protection. While various advantages have been discussed herein, it will be understood that not all implementations necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other implementations are also contemplated. These include implementations that have fewer, additional, and/or different components, steps, features, objects, benefits and advantages. These also include implementations in which the components and/or steps are arranged and/or ordered differently.

Aspects of the present disclosure are described herein with reference to a flowchart illustration and/or block diagram of a method, apparatus (systems), and computer program products according to implementations of the present disclosure. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the figures herein illustrate the architecture, functionality, and operation of possible implementations of systems, methods, and computer program products according to various implementations of the present disclosure. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

While the foregoing has been described in conjunction with exemplary implementations, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various implementations for the purpose of streamlining the disclosure. This method of disclosure is not to be interpreted as reflecting an intention that the claimed implementations have more features than are expressly recited in each claim. Rather, as the following claims reflect, subject matter lies in less than all features of a single disclosed implementation. Thus, the following claims are hereby incorporated into the Detailed Description, with each claim standing on its own as a separately claimed subject matter.

Clause 1. A method comprising: establishing sensor performance characteristics of a physical sensor used in measuring an attribute of a physical system; simulating, by providing input parameters to a process-based model, the physical system to produce simulated data corresponding to state variables of the physical system; replacing, in the simulated data, at least one state variable corresponding to the attribute of the physical system, with a simulated sensor response by applying, to the at least one state variable, the sensor performance characteristics of the physical sensor to corrupt the at least one state variable; and generating a training dataset that includes the simulated data and the input parameters of the process-based model, wherein at least one physical system property of the input parameters or at least one state variable is identified as a training target.

Clause 2. The method of clause 1, further comprising using the training dataset to train a machine learning model to predict a value of the training target as an output.

Clause 3. The method of clause 2, wherein the machine learning model is configured to predict tunnel information using sensor measurements of underground pressure as inputs.

Clause 4. The method of clause 2 further comprising: after the training, using the machine learning model in an inference mode; and using the output to inform an action performed on the physical system.

Clause 5. The method of clause 4 wherein the action performed includes controlling an irrigation system.

Clause 6. The method of clause 4 wherein the action performed includes alerting to suspected presence of a tunnel.

Clause 7. The method of clause 4 wherein the action performed includes recording information related to an environmental regulation.

Clause 8. The method of any of clause 1 to clause 7, wherein the physical system property is a static boundary condition.

Clause 9. The method of any of clause 1 to clause 7, wherein the physical system property is a domain definition.

Clause 10. The method of any of clause 1 to clause 7, wherein the at least one state variable identified as the training target is a variable boundary condition.

Clause 11. The method of any of clause 1 to clause 7, wherein the at least one state variable identified as the training target is an attribute of the physical system that is not measurable by a physical sensor.

Clause 12. The method of any clause 1 to clause 11, wherein the process-based model is a physics-based model or an empirical model.

Clause 13. The method of any of clause 1 to clause 12, wherein the training dataset includes a plurality of training examples, each training example including a time series of the simulated data and a respective training target.

Clause 14. The method of clause 13, wherein the respective training target is an instance in the time series.

Clause 15. The method of any of clause 1 to clause 14, further comprising: performing the simulating and the replacing a plurality of times, each time of the plurality of times corresponding to a scenario of a plurality of scenarios, wherein each scenario is defined by respective input parameters representing a domain definition, initial conditions, and/or boundary conditions of the physical system, wherein each scenario generates at least one respective training example in the training dataset.

Clause 16. The method of any clause 1 to clause 15, wherein the training dataset further includes a measurement from an actual physical sensor as a training target.

Clause 17. The method of clause 1, wherein the physical system property of the input parameters is human generated or human obtained.

Clause 18. The method of any of clause 1 to clause 17, wherein the sensor performance characteristics include experimentally determined sensor transfer functions, repeatability, uncertainty, or spatial weighting.

Clause 19. The method of any of clause 1 to clause 17, wherein the sensor performance characteristics comprise one or more transfer functions computed by characterizing physical sensor performance in response to one or more controlled experimental conditions and the simulated data are corrupted by applying the one or more transfer functions to the simulated data.

Clause 20. The method of any of clause 1 to clause 17, wherein the sensor performance characteristics comprise one or more probabilistic representations of a response of the physical sensor computed by characterizing physical sensor performance in response to one or more controlled experimental conditions and the simulated data are corrupted by applying, to the simulated data, synthetic realizations of sensor uncertainty derived from parametric descriptions of the one or more probabilistic representations.

Clause 21. The method of any of clause 1 to clause 20, wherein the simulated sensor response includes a temperature, a flow rate, a pressure, a concentration, a flux, a rate of flux, an amplitude of a wave, or a frequency of a wave.

Clause 22. The method of any of clause 1 to clause 21, the method further comprising: using the training dataset to train a machine learning model to estimate multiple training targets simultaneously.

Clause 23. A method comprising: simulating interaction of a fluid with an unsaturated porous medium by providing input parameters to a process-based model, the simulating producing simulated data corresponding to physical state variables of the unsaturated porous medium, the physical state variables representing attributes of the fluid in the unsaturated porous medium; generating, from the simulated data, simulated sensor responses that approximate an actual output of a physical sensor; generating a training dataset that includes the simulated data reflecting the simulated sensor responses and physical system properties, wherein at least one physical system property or at least one state variable represented in the simulated data is identified as a training target; and providing the training dataset for training a machine learning model.

Clause 24. The method of clause 23, wherein the physical state variables comprise one or more of a flux state, a storage state, a pressure state, or a nutrition state.

Clause 25. The method of clause 23 or clause 24, wherein the simulated sensor responses include: a) a volumetric water content, b) a pressure of the fluid at one or more depths in the unsaturated porous medium and/or measured at one or more points in time, c) a temperature of the fluid at one or more depths in the unsaturated porous medium and/or measured at one or more points in time, d) rainfall as a function of time, e) irrigation as a function of time, f) air temperature as a function of time, or g) solar insolation as a function of time.

Clause 26. The method of any of clause 23 to clause 25, wherein the simulated data includes data that corresponds to a physical state variable that is not measurable by a physical sensor.

Clause 27. The method of any of clause 23 to clause 26, wherein the simulated data and the simulated sensor responses are for a scenario of a plurality of scenarios and the method further comprises: performing the simulating and generating the simulated sensor responses a plurality of times, wherein each scenario is defined by respective input parameters representing a domain definition, initial conditions, and/or boundary conditions of the physical system, wherein each scenario generates at least one respective training example in the training dataset.

Clause 28. The method of any of clause 23 to clause 27, further comprising: generating the training dataset using measurements obtained from actual physical sensors as additional training targets.

Clause 29. The method of any of clause 23 to clause 28, wherein the machine learning model is configured to predict at least one: (a) unsaturated groundwater flux based on time series sensor measurements of soil water content at one or more depths; (b) unsaturated groundwater content based on time series sensor measurements of soil temperature at one or more depths; (c) unsaturated groundwater flux based on time series sensor measurements of soil temperature at one or more depths; (d) unsaturated groundwater pressure based on sensor measurements of soil water content at one or more depths; or (e) unsaturated groundwater pressure based on time series sensor measurements of soil temperature at one or more depths.

Clause 30. A method comprising: receiving state variables for a physical system that correspond to responses from physical sensors placed in the physical system; receiving physical system properties for the physical system; and obtaining a prediction of an attribute of the physical system by providing the state variables and the physical system properties to a machine learning model, the machine learning model providing the prediction of the attribute, wherein the prediction is used to inform an action performed on the physical system, and wherein the machine learning model has been trained using a training dataset to provide an estimation given state variables and the physical system properties, the training dataset including simulated data that includes simulated sensor responses, input parameters for a process-based model, and the attribute identified as a training target.

Clause 31. The method of clause 30, wherein the prediction relates to a soil property or a soil hydraulic property.

Clause 32. The method of clause 30, wherein the prediction relates to a spatial distribution of soil permeability, a pattern of water applied in an irrigation system, or a pattern of surface infiltration.

Clause 33. The method of any of clause 30, wherein the action performed includes controlling an irrigation system.

Clause 34. The method of clause 30, wherein the action performed includes alerting to suspected presence of a tunnel.

Clause 35. The method of clause 30, wherein the action performed includes recording information related to an environmental regulation.

Clause 36. A computer system comprising: at least one processor; and memory storing instructions that, when executed by the at least one processor, performs the method of clauses 1 to 35.

What is claimed is:

1. A method comprising:
establishing sensor performance characteristics of a physical sensor used in measuring an attribute of a physical system;
simulating, by providing input parameters to a process-based model, the physical system to produce simulated data corresponding to state variables of the physical system;
replacing, in the simulated data, at least one state variable corresponding to the attribute of the physical system, with a simulated sensor response by applying, to the at least one state variable, the sensor performance characteristics of the physical sensor to corrupt the at least one state variable; and
generating a training dataset that includes the simulated data and the input parameters of the process-based model, wherein at least one physical system property of the input parameters or at least one state variable is identified as a training target.
